(19) United States
(12) Patent Application Publication
(10) Pub. No.: US 2026/0123380 A1
(43) Pub. Date: Apr. 30, 2026

(54) SINGLE LAYER PLANAR MULTI-TURN SLICE COIL

(71) Applicant: Intel Corporation, Santa Clara, CA (US)

(72) Inventors: Terry William GILMORE, Ridgefield, WA (US); Zhen ZHOU, Chandler, AZ (US)

(21) Appl. No.: 19/432,221

(22) Filed: Dec. 24, 2025

(51) Int. Cl. H10W 20/20; H10W 44/00; H10W 90/10; H10W 90/26

(52) U.S. Cl. CPC H10W 20/213; H10W 44/501; H10W 90/10; H10W 90/26

(57) ABSTRACT

A device may include a plurality of chiplets stacked on top of each other. Each chiplet includes a central region and an edge region outside the central region; one or more electronic components disposed within the central region; and a plurality of through-chiplet vias extending through the chiplet. The plurality of through-chiplet vias are disposed in the edge region. The device may further include a coil including a plurality of turns formed in at least two chiplets of the plurality of chiplets. Each turn includes at least two through-chiplet vias of at least one chiplet of the plurality of chiplets. The through-chiplet vias of the plurality of through-chiplet vias of the at least two turns of the plurality of turns of the coil are formed in a common plane perpendicular to main surfaces of the plurality of chiplets.

### BACKGROUND

Over the past two decades, processor performance (measured in peak Floating-Point Operations per Second (FLOPS)) has improved at approximately three times every two years, while Dynamic Random Access Memory (DRAM) bandwidth has only scaled about 1.6 times, and interconnect bandwidth just 1.4 times in the same period. This widening gap has pushed memory, rather than compute, into the role of primary bottleneck in Artificial Intelligence (AI) workloads.

### BRIEF DESCRIPTION OF THE DRAWINGS

In the drawings, like reference characters generally refer to the same parts throughout the different views. The drawings are not necessarily to scale, emphasis instead generally being placed upon illustrating the exemplary principles of the disclosure. In the following description, various exemplary embodiments of the disclosure are described with reference to the following drawings, in which:

FIG. 1 depicts a 3D chiplet stack including a plurality of chiplets according to an embodiment;

FIG. 2 depicts a device including a plurality of 3D chiplet stacks and a further die inductively coupled with each other according to an embodiment;

FIG. 3 depicts a top side view of a 3D chiplet stack according to an embodiment;

FIG. 4 depicts a top side view of a portion of the device of FIG. 2 according to an embodiment;

FIG. 5 depicts a bottom side view of a portion of the device of FIG. 2 according to an embodiment;

FIG. 6 depicts a top side view of the device of FIG. 2 according to an embodiment;

FIG. 7 depicts an exemplary portion of a 3D chiplet stack with only one exemplary coil according to an embodiment;

FIG. 8A depicts an exemplary coil;

FIG. 8B depicts the exemplary coil of FIG. 8A together with a host coil;

FIG. 9A depicts a front view of the exemplary coil of FIG. 7 according to an embodiment;

FIG. 9B depicts a three-dimensional view of the exemplary coil of FIG. 7 according to an embodiment;

FIG. 10A depicts a side view of an exemplary coil according to an embodiment;

FIG. 10B depicts a front view of the exemplary coil of FIG. 10A;

FIG. 11A depicts a three-dimensional view of an exemplary coil according to an embodiment;

FIG. 11B depicts a top view of the exemplary coil of FIG. 11A;

FIG. 11C depicts a bottom view of the exemplary coil of FIG. 11A;

FIG. 12A depicts a simulated inductor system of the exemplary coil of FIG. 8A and a host coil;

FIG. 12B depicts a simulated inductor system of the exemplary coil of FIG. 9A and a host coil;

FIG. 13A depicts characteristics of the ohmic resistance versus frequency for the simulated inductor systems of FIG. 12A and FIG. 12B;

FIG. 13B depicts characteristics of the electric parasitic capacity versus frequency for the simulated inductor systems of FIG. 12A and FIG. 12B;

FIG. 13C depicts characteristics of the self-inductance versus frequency and mutual inductance versus frequency for the simulated inductor systems of FIG. 12A and FIG. 12B;

FIG. 13D depicts characteristics of the link insertion loss versus frequency for the simulated inductor systems of FIG. 12A and FIG. 12B;

FIG. 14 depicts an exemplary chip module according to an embodiment;

FIG. 15 depicts a block diagram of the chip module of FIG. 14;

FIG. 16 depicts a flow diagram illustrating a method of manufacturing a device; and

FIG. 17 depicts a flow diagram illustrating a method of manufacturing a device.

### DESCRIPTION

The following detailed description refers to the accompanying drawings that show, by way of illustration, exemplary details and embodiments in which aspects of the present disclosure may be practiced.

The word “exemplary” is used herein to mean “serving as an example, instance, or illustration”. Any embodiment or design described herein as “exemplary” is not necessarily to be construed as preferred or advantageous over other embodiments or designs.

Throughout the drawings, it should be noted that like reference numbers are used to depict the same or similar elements, features, and structures, unless otherwise noted.

The phrase “at least one” and “one or more” may be understood to include a numerical quantity greater than or equal to one (e.g., one, two, three, four, [ . . . ], etc.). The phrase “at least one of” with regard to a group of elements may be used herein to mean at least one element from the group consisting of the elements. For example, the phrase “at least one of” with regard to a group of elements may be used herein to mean a selection of: one of the listed elements, a plurality of one of the listed elements, a plurality of individual listed elements, or a plurality of a multiple of individual listed elements.

The words “plural” and “multiple” in the description and in the claims expressly refer to a quantity greater than one. Accordingly, any phrases explicitly invoking the aforementioned words (e.g., “plural [elements]”, “multiple [elements]”) referring to a quantity of elements expressly refers to more than one of the said elements. For instance, the phrase “a plurality” may be understood to include a numerical quantity greater than or equal to two (e.g., two, three, four, five, [ . . . ], etc.).

The phrases “group (of)”, “set (of)”, “collection (of)”, “series (of)”, “sequence (of)”, “grouping (of)”, etc., in the description and in the claims, if any, refer to a quantity equal to or greater than one, i.e., one or more. The terms “proper subset”, “reduced subset”, and “lesser subset” refer to a subset of a set that is not equal to the set, illustratively, referring to a subset of a set that contains less elements than the set.

The term “data” as used herein may be understood to include information in any suitable analog or digital form, e.g., provided as a file, a portion of a file, a set of files, a signal or stream, a portion of a signal or stream, a set of signals or streams, and the like. Further, the term “data” may also be used to mean a reference to information, e.g., in form of a pointer. The term “data”, however, is not limited to the aforementioned examples and may take various forms and represent any information as understood in the art.

The terms “processor” or “controller” as, for example, used herein may be understood as any kind of technological entity that allows handling of data. The data may be handled according to one or more specific functions executed by the processor or controller. Further, a processor or controller as used herein may be understood as any kind of circuit, e.g., any kind of analog or digital circuit. A processor or a controller may thus be or include an analog circuit, digital circuit, mixed-signal circuit, logic circuit, processor, microprocessor, Central Processing Unit (CPU), Graphics Processing Unit (GPU), Digital Signal Processor (DSP), Field Programmable Gate Array (FPGA), integrated circuit, Application Specific Integrated Circuit (ASIC), etc., or any combination thereof. Any other kind of implementation of the respective functions, which will be described below in further detail, may also be understood as a processor, controller, or logic circuit. It is understood that any two (or more) of the processors, controllers, or logic circuits detailed herein may be realized as a single entity with equivalent functionality or the like, and conversely that any single processor, controller, or logic circuit detailed herein may be realized as two (or more) separate entities with equivalent functionality or the like.

As used herein, “memory” is understood as a computer-readable medium (e.g., a non-transitory computer-readable medium) in which data or information can be stored for retrieval. References to “memory” included herein may thus be understood as referring to volatile or non-volatile memory, including random access memory (RAM), read-only memory (ROM), flash memory, solid-state storage, magnetic tape, hard disk drive, optical drive, 3D XPoint™, among others, or any combination thereof. Registers, shift registers, processor registers, data buffers, among others, are also embraced herein by the term memory. The term “software” refers to any type of executable instruction, including firmware.

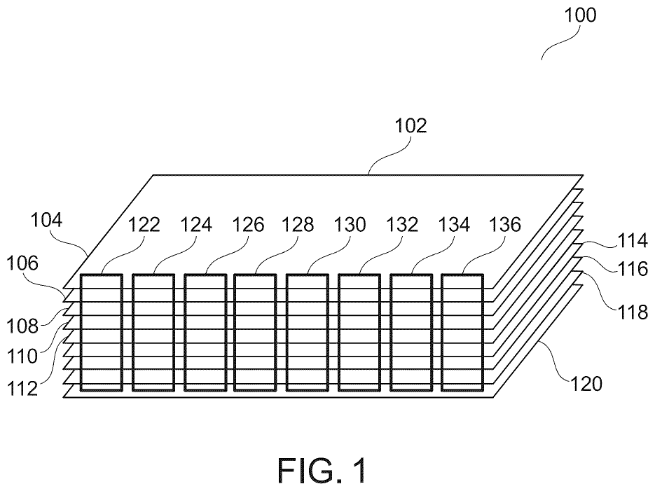

To overcome the memory bottleneck while leveraging the existing process technology and package paradigm. FIG. 1 shows a (three-dimensional) stack which may be implemented as a Z Axis Memory Stack (ZAM). ZAM includes a (three-dimensional) stack of a plurality of chiplets (in other words a plurality of dies). Each chiplet may include one or more electronic components, e.g. one or more, e.g. thousands, millions or even billions or more memory cells. ZAM intends to expand the memory capacity in the proximity of the processing units such as central processing units (CPUs), graphical processing units (GPUs), tensor processing units (TPUs), or application-specific integrated circuit (ASCI) accelerators (XPU) by rotating the 3D chiplet stack (e.g. a 3D memory stack) of a plurality of chiplets (e.g. by 90°) to reduce the lateral area footprint of each memory stack. Communication between a memory stack (e.g. a ZAM) and a processor (e.g. a processor unit (e.g. any of the processing units mentioned before)) can be achieved through inductive coupling (e.g. by an inductive link) between the memory stack and the processor.

To efficiently utilize an inductive link, the inductive link should have a mutual inductance (Lm) greater or equal to a Lm provided by a conventional transceiver design. To achieve such a Lm for a given communication distance, both coils (one or more coils of a memory stack, e.g. in a ZAM slice (a slice may be understood as a plurality of chiplets stacked over one another), and one or more coils of a processor, e.g. on a processor die) usually need multiple (in other words a plurality of) turns.

Various aspects illustratively provide a single layer planar multi-turn (SLPMT) slice coil design to achieve an improved H-Field coupling between the slice and a host and potentially mitigate the impact of SLPMT-generated H-Field interference on the central circuitry region.

As will be disclosed in more detail below, a coil design in various aspects may provide:
a higher coupling between a respective slice coil and a respective host coil;
larger achievable bandwidth, and better scalability for future generations of memory; and/or
less concern of interfering the (logic and/or memory) circuitry of the slice.

FIG. 1 shows a device 100 that includes a 3D chiplet stack 102. The 3D chiplet stack 102 includes a plurality of (multiple) chiplets 104, 106, 108, 110, 112, 114, 116, 118. The chiplets 104, 106, 108, 110, 112, 114, 116, 118 are stacked on top of each other to form the chiplet stack 102. Optionally, the 3D chiplet stack 102 includes a substrate 120. The substrate 120 may be a single base-die (e.g. the bottommost chiplet 120 of the 3D chiplet stack 102). In general, the plurality of chiplets 104, 106, 108, 110, 112, 114, 116, 118 may include an arbitrary number of chiplets, e.g. three, four, five, six, seven, eight, nine, ten, more than ten, up to 15, more than 15, up to 20, more than 20, up to 30, more than 30, up to 50, more than 50, up to 70, more than 70, up to 100, or even more chiplets.

Each chiplet of the plurality of chiplets 104, 106, 108, 110, 112, 114, 116, 118 may include:
one or more electronic components (e.g. any kind of logic circuit such as e.g. a processor, or any kind of memory circuit); and
a plurality of connections electrically connecting the one or more electronic components within the chiplet, the plurality of connections formed in one or more metal layers (the plurality of connections may also provide a connection interface to another chiplet or to one or more electrically conductive connections as will be described in more detail below, e.g. to receive power, connect to a reference potential (e.g. ground potential) or receive or provide e.g. test signals or debug signals);
main surfaces (e.g. two main surfaces disposed at opposite sides of the chiplet) and side surfaces (e.g. four side surfaces disposed between the two main surfaces), wherein the main surfaces of adjacent chiplets of the plurality of chiplets 104, 106, 108, 110, 112, 114, 116, 118 face each other;
a central region and an edge region outside the central region (by way of example, the edge region may partially or completely surround the central region—the edge region is located between the central region and at least one side surface of the side surfaces);
the one or more electronic components are disposed within the central region;
a plurality of through-chiplet vias (e.g. a plurality of through-silicon vias) extending through the chiplet from one main surface of the main surfaces to another main surface of the main surfaces.

The plurality of through-chiplet vias may be disposed in the edge region.

A memory circuit may include or be a volatile memory circuit, for example a DRAM (Dynamic Random Access Memory) or a non-volatile memory circuit, for example a PROM (Programmable Read Only Memory), an EPROM (Erasable PROM), EEPROM (Electrically Erasable PROM), or a flash memory, e.g., a floating gate memory, a charge trapping memory, an MRAM (Magnetoresistive Random Access Memory) or a PCRAM (Phase Change Random Access Memory), and the like.

The base die 120 may include one or more logic circuits (e.g. one or more processors) and/or one or more power supply circuits.

The device 100 may further include one or more coils 122, 124, 126, 128, 130, 132, 134, 136. As will be described in more detail below, each coil of the one or more coils 122, 124, 126, 128, 130, 132, 134, 136 includes a plurality of turns formed in at least two chiplets of the plurality of chiplets 104, 106, 108, 110, 112, 114, 116, 118. Each turn includes at least two through-chiplet vias of at least one chiplet of the plurality of chiplets. The through-chiplet vias of the plurality of through-chiplet vias of the at least two turns of the plurality of turns of the coil are formed in a common plane. The common plane is perpendicular to the main surfaces of the plurality of chiplets.

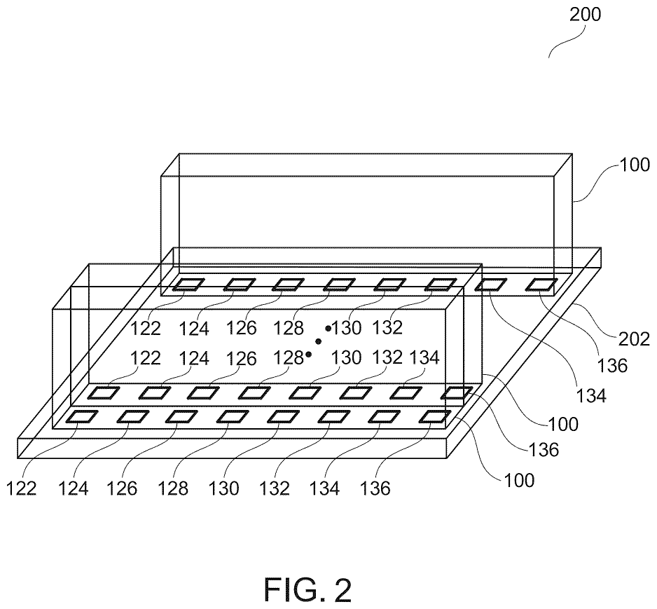

It is to be noted that FIG. 1 and FIG. 2 only illustrate the general structure of the devices. By way of example, in various aspects, the one or more coils 122, 124, 126, 128, 130, 132, 134, 136 are implemented by through-chiplet vias and thus by structures running through the material of the chiplets 104, 106, 108, 110, 112, 114, 116, 118 and are not deposited on the surfaces of the chiplets 104, 106, 108, 110, 112, 114, 116, 118. This will be described in more detail below.

FIG. 2 shows a device 200 in accordance with various aspects. The device 200 includes a plurality of the devices 100 as shown in FIG. 1. Furthermore, the device 200 includes a further die 202. The further die 202 includes one or more processors (not shown in FIG. 2) and one or more further coils (not shown in FIG. 2). The further die 202 is inductively coupled with the devices 100 via one or more coils of the respective device 100 and the one or more further coils of the further die 202. In various aspects, the further die 202 may include logic circuitry to forward data from one or more devices 100 to a processor die (and/or from the processor die to one or more devices 100), as will be described further below. The one or more further coils may be disposed on or over a surface of the further die 202. The one or more further coils may be electrically connected to at least one further electronic component of the one or more further electronic components (e.g. the logic circuitry to forward data from one or more devices 100 to a processor die (and/or from the processor die to one or more devices 100). The further die 202 (e.g. the one or more further coils of the further die 202) and the one or more coils 122, 124, 126, 128, 130, 132, 134, 136 are facing each other to allow an inductive coupling between a respective chiplet of the plurality of chiplets 104, 106, 108, 110, 112, 114, 116, 118 and the further die 202.

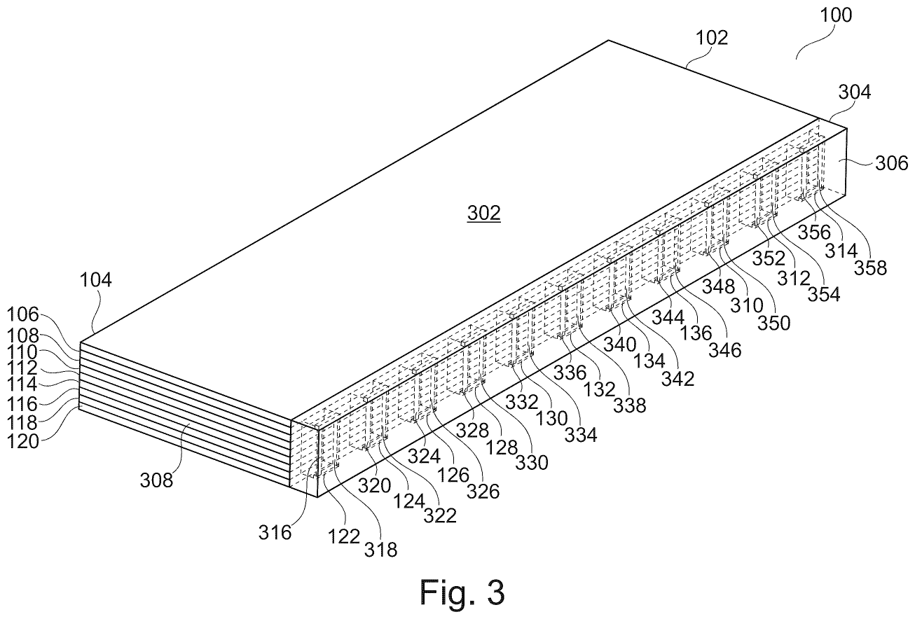

FIG. 3 depicts a three-dimensional top side view of the 3D chiplet stack 102 of FIG. 1 according to an embodiment. As shown in FIG. 3, the one or more coils 122, 124, 126, 128, 130, 132, 134, 136 of the 3D chiplet stack 102 are formed within the plurality of chiplets 104, 106, 108, 110, 112, 114, 116, 118. Each chiplet of the plurality of chiplets 104, 106, 108, 110, 112, 114, 116, 118 has a central region 302 and an edge region 304. The edge region 304 is shown as a transparent portion of the respective chiplet of the plurality of chiplets 104, 106, 108, 110, 112, 114, 116, 118. Each chiplet has two main surfaces (a top main surface 306 of the topmost chiplet 104 is shown in FIG. 3) and four side surfaces (first side surface 308 and second side surfaces 310 are shown in FIG. 3). In the example shown in FIG. 3, each edge region 304 of a respective chiplet is disposed between the central region 302 of the respective chiplet and a side surface of the respective chiplet (in the example shown in FIG. 3 the first side surface 308). It is to be noted that FIG. 3 shows additional coils 310, 312, 314 which are similar to the one or more coils 122, 124, 126, 128, 130, 132, 134, 136 of the 3D chiplet stack 102 as shown in FIG. 1.

Each coil of the one or more coils 122, 124, 126, 128, 130, 132, 134, 136, 310, 312, 314 of the 3D chiplet stack 102 is formed by a plurality of through-chiplet vias (e.g. through-silicon vias) 316, 318, 320, 322, 324, 326, 328, 330, 332, 334, 336, 338, 340, 342, 344, 346, 348, 350, 352, 354, 356, 358 running (in other words extending) through a plurality of (e.g. all) chiplets of the plurality of chiplets 104, 106, 108, 110, 112, 114, 116, 118. The through-chiplet vias may be formed by an electrically conductive material, e.g. a metal, e.g. copper or aluminum, or the like. The through-chiplet vias may extend perpendicular to the main surfaces of the chiplets. By way of example, two through-chiplet vias of adjacent chiplets are mechanically and electrically coupled with each other to form a leg or a portion of a leg of a respective coil. The through-chiplet vias may have a diameter in the range from about 1 μm to about 100 μm, e.g. in the range from about 2 μm to about 50 μm. Other dimensions of the through-chiplet vias may be possible, if desired.

FIG. 4 depicts a three-dimensional top side view of a portion of the device 200 of FIG. 2 according to an embodiment.

In various aspects, the device 200 may have a thickness (in a direction perpendicular to the main surfaces of the chiplets of the 3D chiplets) in the range from about 2 mm to about 20 mm, e.g. in the range from about 3 mm to about 15 mm, e.g. in the range from about 5 mm to about 10 mm (e.g. about 6 mm). Furthermore, the device 200 may have a length (in a direction parallel to the main surfaces of the chiplets of the 3D chiplets) in the range from about 4 mm to about 40 mm, e.g. in the range from about 6 mm to about 30 mm, e.g. in the range from about 10 mm to about 20 mm (e.g. about 12 mm). Moreover, the device 200 may have a width (in a direction parallel to the main surfaces of the chiplets of the 3D chiplets) in the range from about 1 mm to about 15 mm, e.g. in the range from about 2 mm to about 10 mm, e.g. in the range from about 3 mm to about 6 mm (e.g. about 3.7 mm).

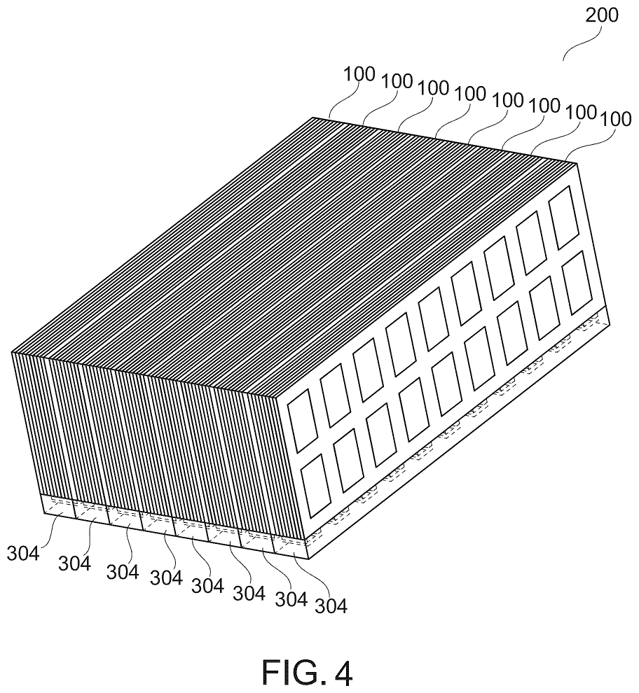

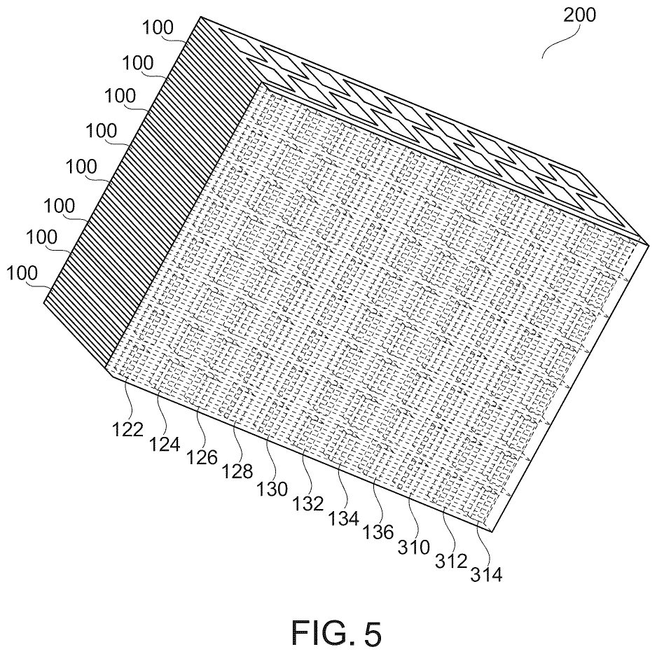

FIG. 5 depicts a three-dimensional bottom side view of a portion of the device 200 of FIG. 2 according to an embodiment.

FIG. 6 depicts a three-dimensional top side view of the device 200 of FIG. 2 according to an embodiment. FIG. 6 shows the one or more further coils 602, 604, 606, 608, 610, 612, 614, 616, 618, 620, 622, 624, 626, 628, 630 disposed on the further die 202 facing the one or more coils 122, 124, 126, 128, 130, 132, 134, 136 of the chiplets of the plurality of chiplets 104, 106, 108, 110, 112, 114, 116, 118 of the plurality of 3D chiplet stacks 100 of the device 200.

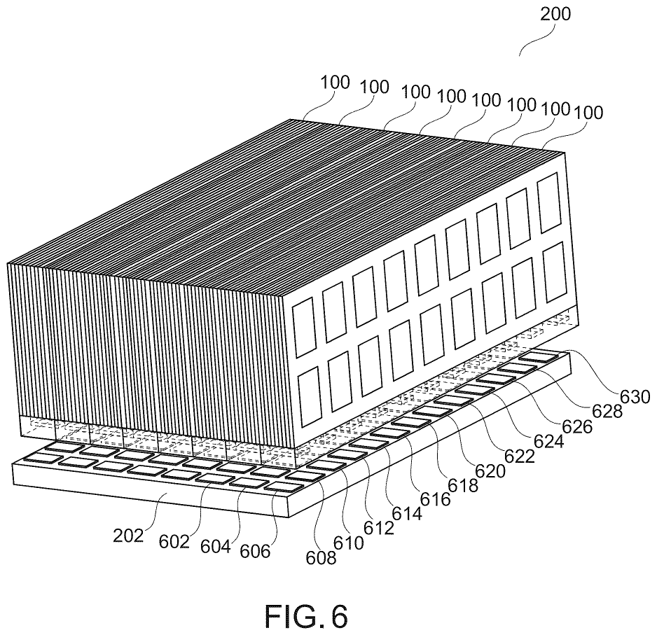

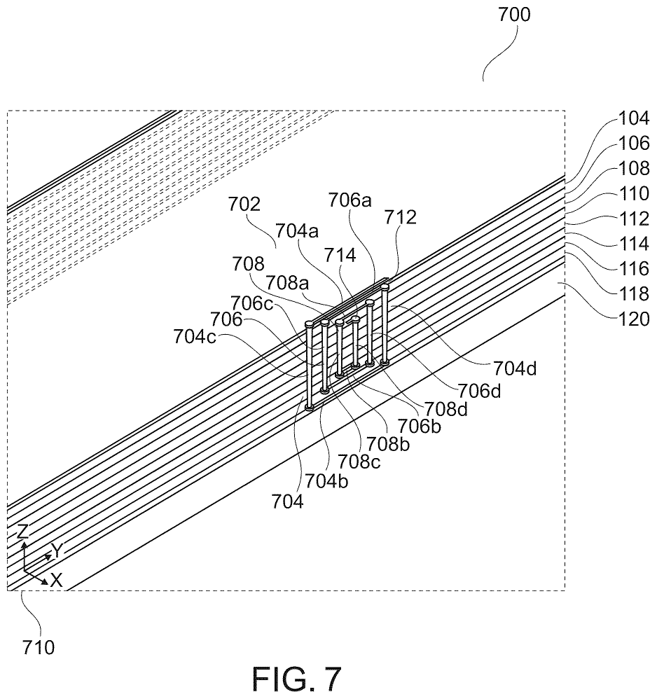

FIG. 7 depicts an exemplary portion of a 3D chiplet stack 700 with only one exemplary coil according to an embodiment. The 3D chiplet stack 700 may be similar to the 3D chiplet stack 100 of FIG. 1, but only including a single coil 702, for illustration purposes.

The coil 702 includes a plurality of turns (in other words windings), in this example three turns 704, 706, 708.

In this example, all turns are (e.g. completely) formed in the same plane (in FIG. 7 the same y-z plane as defined by coordinate system 710). The plane extends perpendicular to the main surfaces of the chiplets 104, 106, 108, 110, 112, 114, 116, 118 of the 3D chiplet stack 700. The coil 702 (in general a plurality of coils) is formed (partially or completely) within the (material of) the chiplets 104, 106, 108, 110, 112, 114, 116, 118. Furthermore, in this example, the turns 704, 706, 708 are of different sizes. By way of example, a first turn 704 forms an outer turn of the coil 702 and has the largest size. A second turn 706 of the coil 702 is formed in the same plane as the first turn 704 and is formed within the inner space of the first turn 704. A third turn 708 of the coil 702 is formed in the same plane as the first turn 704 and the second turn 706 and is formed within the inner space of the second turn 706. The turns 704, 706, 708 of the coil 702 are electrically coupled in series with each other to form the coil 702.

In various aspects, the first turn 704 includes two horizontal arms (which may also be referred to as two horizontal connections) 704a, 704b and two vertical legs 704c, 704d. The two horizontal arms 704a, 704b are formed by electrically conductive connections (e.g. electrically conductive lines, e.g. metal lines) formed in or on or over a respective chiplet). By way of example, a first horizontal arm 704a of the first turn 704 is formed in or on or over the topmost chiplet 104 of the 3D chiplet stack 700. A first terminal 712 of the coil 702 is provided by one end of the first horizontal arm 704a. The first terminal 712 may be coupled to a first electric potential, e.g. provided by a circuit. A first vertical leg 704c of the first turn 704 is formed by a plurality of through-chiplet vias (each through-chiplet via (e.g. through silicon via) extends completely through a respective chiplet, e.g. from one main surface of the chiplet to the other (opposite) main surface of the chiplet). The plurality of through-chiplet vias forming the first vertical leg 704c of the first turn 704 are electrically connected in series. Furthermore, a first (upper) end of the first vertical leg 704c of the first turn 704 is connected to another end of the first horizontal arm 704a which is opposite to the end coupled to the first electric potential. A second horizontal arm 704b of the first turn 704 is formed in or on or over the bottommost chiplet 118 of the 3D chiplet stack 700. A first end of the second horizontal arm 704b of the first turn 704 is connected to a second (bottom) end of the first vertical leg 704c of the first turn 704. A second vertical leg 704d of the first turn 704 is formed by a plurality of further through-chiplet vias (each through-chiplet via (e.g. through silicon via) extends completely through a respective chiplet, e.g. from one main surface of the chiplet to the other (opposite) main surface of the chiplet). The plurality of through-chiplet vias forming the second vertical leg 704d of the first turn 704 are electrically connected in series. Furthermore, a first (bottom) end of the second vertical leg 704d of the first turn 704 is connected to a second end of the second horizontal arm 704b of the first turn 704. The second end of the second horizontal arm 704b of the first turn 704 is opposite the first end of the second horizontal arm 704b of the first turn 704. A second (upper) end of the second vertical leg 704d of the first turn 704 may terminate in the second uppermost chiplet 106. Illustratively, the second (upper) end of the second vertical leg 704d of the first turn 704 forms the end of the first turn 704.

The second turn 706 includes two horizontal arms 706a, 706b and two vertical legs 706c, 706d. The two horizontal arms 706a, 706b are formed by electrically conductive connections (e.g. electrically conductive lines, e.g. metal lines) formed in or on or over a respective chiplet). By way of example, a first horizontal arm 706a of the second turn 706 is formed in or on or over the second topmost chiplet 106 of the 3D chiplet stack 700. A first end of the second horizontal arm 706a is connected to the second end of the second vertical leg 704d of the first turn 704. A first vertical leg 706c of the second turn 706 is formed by a plurality of through-chiplet vias. The plurality of through-chiplet vias forming the first vertical leg 706c of the second turn 706 are electrically connected in series. Furthermore, a first (upper) end of the first vertical leg 706c of the second turn 706 is connected to a second end of the first horizontal arm 706a of the second turn 706 which is opposite to the first end of the first horizontal arm 706a of the second turn 706. A second horizontal arm 706b of the second turn 706 is formed in or on or over the second bottommost chiplet 116 of the 3D chiplet stack 700. A first end of the second horizontal arm 706b of the second turn 706 is connected to a second (bottom) end of the first vertical leg 706c of the second turn 706. A second vertical leg 706d of the second turn 706 is formed by a plurality of further through-chiplet vias (each further through-chiplet via (e.g. further through silicon via) extends completely through a respective chiplet, e.g. from one main surface of the chiplet to the other (opposite) main surface of the chiplet). The plurality of further through-chiplet vias forming the second vertical leg 706d of the second turn 706 are electrically connected in series. Furthermore, a first (bottom) end of the second vertical leg 706d of the second turn 706 is connected to a second end of the second horizontal arm 706b of the second turn 706. The second end of the second horizontal arm 706b of the second turn 706 is opposite to the first end of the second horizontal arm 706b of the second turn 706. A second (upper) end of the second vertical leg 706d of the first turn 706 may terminate in the third uppermost chiplet 108. Illustratively, the second (upper) end of the second vertical leg 706d of the second turn 706 forms the end of the second turn 706.

The third turn 708 includes two horizontal arms 708a, 708b and two vertical legs 708c, 708d. The two horizontal arms 708a, 708b are formed by electrically conductive connections (e.g. electrically conductive lines, e.g. metal lines) formed in or on or over a respective chiplet. By way of example, a first horizontal arm 708a of the third turn 708 is formed in or on or over the third topmost chiplet 108 of the 3D chiplet stack 700. A first end of the second horizontal arm 708a is connected to the second end of the second vertical leg 706d of the second turn 706. A first vertical leg 708c of the third turn 708 is formed by a plurality of through-chiplet vias. The plurality of through-chiplet vias forming the first vertical leg 708c of the third turn 708 are electrically connected in series. Furthermore, a first (upper) end of the first vertical leg 708c of the third turn 708 is connected to a second end of the first horizontal arm 708a of the third turn 708 which is opposite to the first end of the first horizontal arm 708a of the third turn 708.

A second horizontal arm 708b of the third turn 708 is formed in or on or over the third bottommost chiplet 114 of the 3D chiplet stack 700. A first end of the second horizontal arm 708b of the third turn 708 is connected to a second (bottom) end of the first vertical leg 708c of the third turn 708. A second vertical leg 708d of the third turn 708 is formed by a plurality of further through-chiplet vias (each further through-chiplet via (e.g. further through silicon via) extends completely through a respective chiplet, e.g. from one main surface of the chiplet to the other (opposite) main surface of the chiplet. The plurality of further through-chiplet vias forming the second vertical leg 708d of the third turn 708 are electrically connected in series. Furthermore, a first (bottom) end of the second vertical leg 708d of the third turn 708 is connected to a second end of the second horizontal arm 708b of the third turn 708. The second end of the second horizontal arm 708b of the third turn 708 is opposite to the first end of the second horizontal arm 708b of the third turn 708. A second (upper) end of the second vertical leg 708d of the third turn 708 may terminate in the fourth uppermost chiplet 110. Illustratively, the second (upper) end of the second vertical leg 708d of the third turn 708 forms the end of the third turn 708. The second (upper) end of the second vertical leg 708d of the third turn 708 may be coupled to a second electric potential, e.g. a reference potential, e.g. a ground potential. The second (upper) end of the second vertical leg 708d of the third turn 708 provides a second terminal 714 of the coil 702. This example provides for a single-ended coil design. In this example, the second terminal 714 of the coil 702 may be a controller terminal configured to receive a control potential to control the current flow through the coil 702.

However, in an alternative, the second (upper) end of the second vertical leg 708d of the third turn 708 may be coupled to the second electric potential being provided by a circuitry so that the first and second electric potentials result in a differential signal processing by the coil without a fixed reference potential. In other words, in this example, the first and second electric potentials may both vary over time. In this example, the first terminal 712 and the second terminal 714 of the coil 702 may be controller terminals configured to receive (different) control potentials to control the current flow through the coil 702.

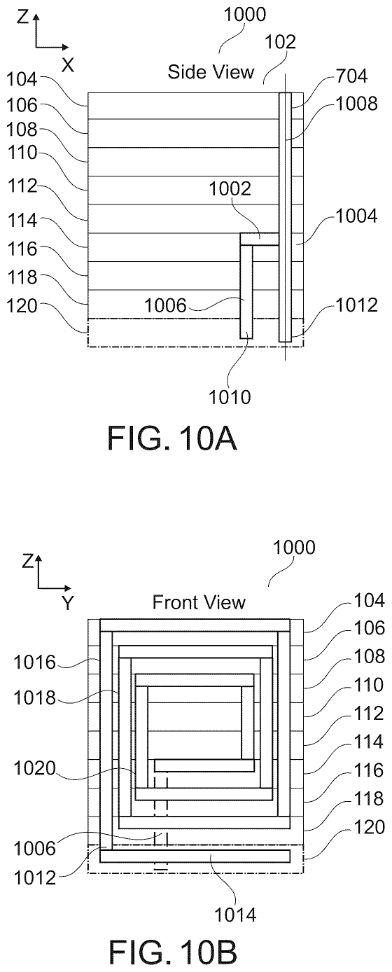

In various aspects, the 3D chiplet stack 700 (as shown in FIG. 7), 1000 (as shown in FIG. 10A) may further include a controller coupled to the controller terminal(s). The controller may be provided in any chiplet, e.g. in the uppermost chiplet 104, in the bottommost chiplet 118, or optionally in the base die 120.

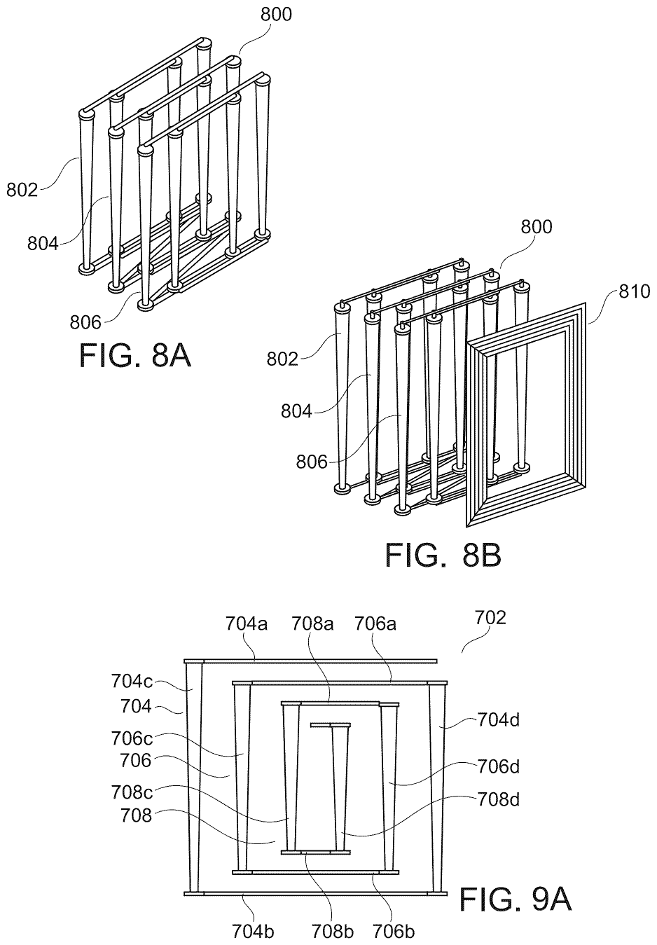

FIG. 8A depicts an exemplary coil 800. Through-chiplet vias of different turns of the coil 800 of FIG. 8A are disposed in different planes.

In this example, the coil includes a plurality of turns 802, 804, 806 extending towards the center of the 3D chiplet stack (e.g. 3D chiplet stack 102), also referred to as slice. Throughout this disclosure, this design will be referred as “Benchmark”. The turns 802, 804, 806 in this design are stretched towards the center of the 3D chiplet stack (e.g. 3D chiplet stack 102) where the circuitry (logic and/or memory) resides. In addition, each turn 802, 804, 806 has its own coupling distance with respect to a host coil 810 (e.g. on the further die 202) as illustrated in FIG. 8B. Stretching the inductive coil 700 toward the center of slice can cause some concern of EMI in the slice circuitry and power delivery network.

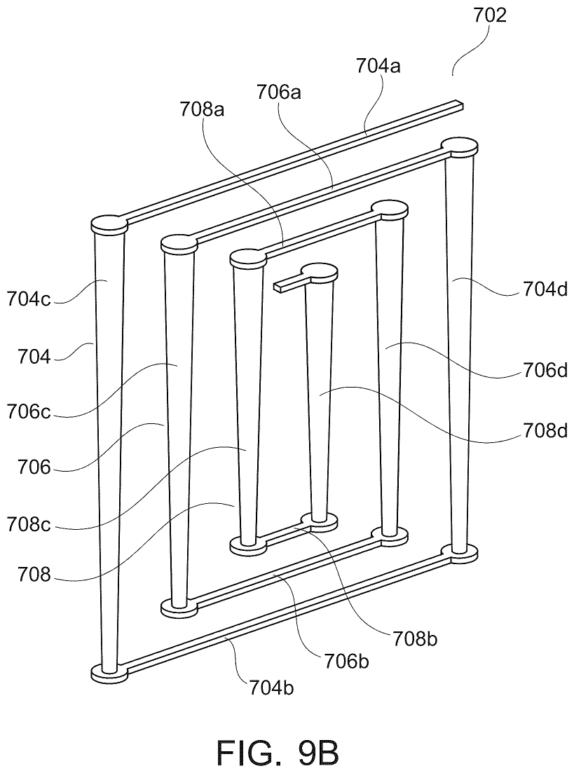

FIG. 9A depicts a three-dimensional front view of the exemplary coil 702 of FIG. 7 according to an embodiment. FIG. 9B depicts a side view of the exemplary coil 702 of FIG. 7 according to an embodiment.

FIG. 10A depicts a side view of an exemplary coil 1000 according to an embodiment and FIG. 10B depicts a front view of the exemplary coil 1000 of FIG. 10A.

In addition to FIG. 7 which shows the coil 702 without a connection of the respective end terminals 712, 714 of the coil 702, FIG. 10A and FIG. 10B illustrate the connection to external circuitry. By way of example, as shown in FIG. 10A, the coil 1000 has an electrically conductive line 1002 connected to the second (coil inner) end terminal 1004 and extending out of the common plane (which is the y-z-plane 1008 in this example) of the turns of the coil 7000. In this example, the coil 1000 further includes a plurality of out-of-common-plane through-chiplet vias serially connected to each other to form an electrically serial connection 1006 from the electrically conductive line 1002 through some chiplets of the plurality of chiplets “down” to the bottommost chiplet 118, and optionally even to the base die 120. The electrically serial connection 1006 may end in a first coil terminal 1010.

Another difference of the coil 1000 of FIG. 10A and FIG. 10B with respect to the coil 702 of FIG. 7 is that a second coil terminal 1012 of the coil 1000 is not provided at the top of the coil (and thus e.g. at the uppermost chiplet (e.g. chiplet 104)). In contrast thereto, as shown in FIG. 10A, the second coil terminal 1012 of the coil 1000 is provided at the bottom of the coil 1000, optionally even extending into the optional base die 120. The second coil terminal 1012 of the coil 1000 may be connected to a conductive structure 1014 (e.g. conductive line), e.g. a metal structure (e.g. metal line). The conductive structure 1014 may be formed in or on the base die 120 and may be implemented in a Back-end-of-Line metal structure or as a redistribution structure (e.g. a redistribution layer).

As shown in FIG. 10B illustrating a front view of the coil 1000, the coil 1000 may also have a plurality of (e.g. three) turns 1016, 1018, 1020, which are similar to the turns 704, 706, 708 with the differences described above.

In various aspects, if desired or needed, one or more additional coils may be provided which may be tied into lateral connection and repeated. Each coil of the plurality of coils may be provided in different respective common planes which are perpendicular to the main surfaces of the chiplets).

Depending on how the turns are placed relatively for the 3D chiplet stack 700, 1000, the Lm of the inductive link at a given communication distance can vary, so does the link bandwidth. Moreover, the coil design of a 3D chiplet stack 700, 1000 can trigger the electromagnetic interference (EMI) concern on ZAM circuitry. In various aspects, a single-layer multi-turn coil (SLMT coil) design on the 3D chiplet stack (which may also be referred to as slice) (e.g. 3D chiplet stack 700, 1000) can maintain the mutual coupling inductance, expand the bandwidth, and mitigate the concern of EMI.

As shown in FIGS. 7, 9A, 9B, 10A and 10B, the 3D chiplet stack coil in accordance with these examples is constituted by multiple through-chiplet vias with different heights and those through-chiplet vias are interconnected by planar transmission lines on different layers of the 3D chiplet stack (and thus in different chiplets) to form multi-turns of the coil. In the configuration shown in the coil 702, 1000 in FIGS. 7, 9A, 9B, 10A and 10B, the 3D chiplet stack coil and an optional transceiver circuitry is connected to a circuitry on the uppermost chiplet (top chiplet) of the 3D chiplet stack 700. As shown in FIGS. 7, 9A, 9B, 10A and 10B, the 3D chiplet stack coil 702 is placed along the edge of the 3D chiplet stack (in other words in the edge region of the 3D chiplet stack and thus in the edge regions of the chiplets in which the 3D chiplet stack coil is implemented), and hence it is further away from the center of the 3D chiplet stack (in other words in the center region of the 3D chiplet stack and thus in the center regions of the chiplets in which the 3D chiplet stack coil is implemented) where the majority of memory circuitries are located.

As shown in FIGS. 10A and 10B, in various aspects, the 3D chiplet stack coil 1000 may be connected to the circuitry (e.g. logic circuitry or memory circuitry) in the bottommost chiplet 118, or even in the base die (e.g. base die 120) rather than to the circuitry (e.g. logic circuitry or memory circuitry) on the top (uppermost) chiplet 104.

In the examples shown in FIGS. 7, 9A, 9B, 10A and 10B, 20, the first turn 704, 1016 of the plurality of turns 704, 706, 708, 1016, 1018, 1020 has a first through-chiplet extension length representing the length of a coil leg (e.g. the first vertical leg 704c, 1016c of the first turn 704, 1016 including through-chiplet vias of the first turn 704, 1016 of a plurality of chiplets. The second turn 706, 1018 of the plurality of turns 704, 706, 708, 1016, 1018, 1020 has a second through-chiplet extension length representing the length of a coil leg (e.g. the first vertical leg 706c, 1018c of the second turn 706, 1018) of the second turn 706, 1018 including through-chiplet vias of the second turn 706, 1018 of a plurality of chiplets. The first through-chiplet extension length is larger than the second through-chiplet extension length. In other words, the first vertical leg 702c of the first turn 702 includes more through-chiplet vias than the first vertical leg 704c of the second turn 704.

Similarly, the third turn 708, 1020 of the plurality of turns 704, 706, 708, 1016, 1018, 1020 has a third through-chiplet extension length representing the length of a coil leg (e.g. the first vertical leg 708c, 1020c of the third turn 708, 1020) of the third turn 708, 1020 including a through-chiplet via of the third turn 708, 1020 of at least one chiplet. The first through-chiplet extension length and the second through-chiplet extension length are larger than the third through-chiplet extension length, and so on for each additional turn of the coil. In these examples, an electrically conductive connection 704a, 1016a of the plurality of electrically conductive connections of the first turn 704, 1016 and an electrically conductive connection 706a, 1018a of the plurality of electrically conductive connections of the second turn are disposed in different chiplets of the 3D chiplet stack. In other words, the first vertical leg 704c of the second turn 704 includes more through-chiplet vias than the first vertical leg 706c of the third turn 706.

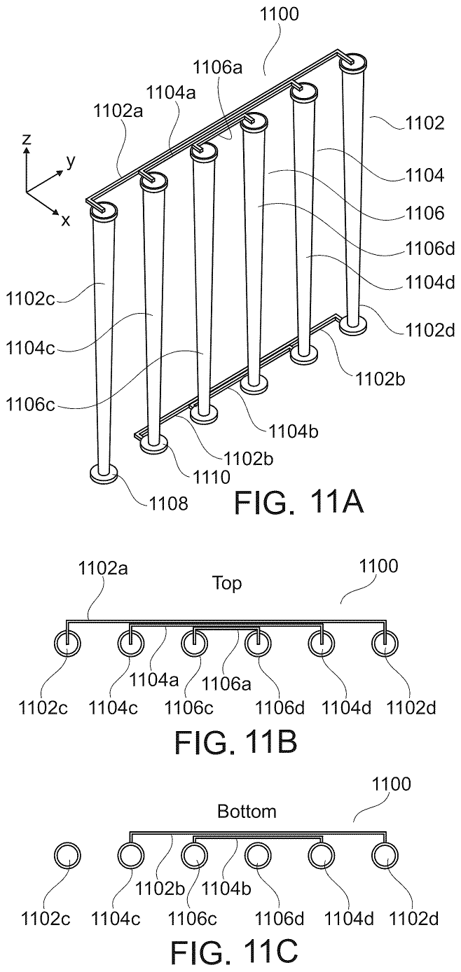

FIGS. 11A to 11C show another aspect of a coil 1100 including a plurality of through-chiplet vias, which may be provided in a similar manner as the coils 702, 1000 described above. To avoid repetition, mainly the differences between the coil 1100 of FIGS. 11A to 11C and the coils 702 and 1000 of FIGS. 7, 9A, 9B, 10A, 10B will be described below. With regard to the common features of the coils 702, 1000 and 1100, reference is made to the description of the coils 702 and 1000 of FIGS. 7, 9A, 9B, 10A, 10B.

In the example of the coil 1100 of FIGS. 11A to 11C, the connection between turns may be provided (in other words take place) on top or on bottom of the 3D chiplet stack. The design may not include inter-layer connections between the through-chiplet vias and may therefore simplify the fabrication process.

The coil 1100 includes a plurality of (e.g. three, in general any desired number) of turns 1102, 1104, 1106. Each turn 1102, 1104, 1106 includes two horizontal arms and two vertical legs. In this example, all vertical legs of all turns (e.g. turns 1102, 1104, 1106) have the same length. Furthermore, all vertical legs of all turns (e.g. turns 1102, 1104, 1106) may be located in the same plane, which plane is perpendicular to the main surfaces of the chiplets of the 3D chiplet stack (e.g. 3D chiplet stack 700 of FIG. 7). The electrically conductive connections (e.g. electrically conductive lines, e.g. metal lines) forming the first horizontal arms of different turns 1102, 1104, 1106 of the coil 1100 may be in a common first horizontal plane, which is parallel to the main surfaces of the chiplets of the 3D chiplet stack (e.g. 3D chiplet stack 700 of FIG. 7). The electrically conductive connections (e.g. electrically conductive lines, e.g. metal lines) forming the second horizontal arms of different turns 1102, 1104, 1106 of the coil 1100 may be in a common second horizontal plane, which is parallel to the main surfaces of the chiplets of the 3D chiplet stack (e.g. 3D chiplet stack 700 of FIG. 7), but different from the first horizontal plane. In various aspects, all first horizontal arms 1102a, 1104a, 1106a may be formed in or on or over the same chiplet (e.g. in the uppermost chiplet 104 of the 3D chiplet stack 102). All second horizontal arms 1102b, 1104b may also be formed in or on or over the same chiplet (e.g. in the bottommost chiplet 118 of the 3D chiplet stack 102). The first horizontal arms 1102a, 1104a, 1106a are formed in or on or over a different chiplet than the chiplet in which the second horizontal arms 1102b, 1104b are formed.

In the example of FIG. 11A, the first turn 1102 includes a first vertical leg 1102c, a first horizontal arm 1102a, a second vertical leg 1102d and a second horizontal arm 1102b, which are connected in series with each other. A first terminal 1108 of the coil 1100 is provided by a first (in FIG. 11A bottom) end of the first vertical leg 1102c. The first terminal 1108 may be coupled to a first electric potential, e.g. provided by a circuit. The first vertical leg 1102c of the first turn 1102 is formed by a plurality of through-chiplet vias (each through-chiplet via (e.g. through silicon via) extends completely through a respective chiplet, e.g. from one main surface of the chiplet to the other (opposite) main surface of the chiplet). The plurality of through-chiplet vias forming the first vertical leg 1102c of the first turn 1102 are electrically connected in series. The first horizontal arm 1102a of the first turn 1102 may be formed in or on or over the topmost chiplet 104 of the 3D chiplet stack 700. Furthermore, a second (in FIG. 11A upper) end of the first vertical leg 1102c of the first turn 1102 is connected to a first end of the first horizontal arm 1102a. The second vertical leg 1102d of the first turn 1102 is formed by a plurality of further through-chiplet vias (each through-chiplet via (e.g. through silicon via) extends completely through a respective chiplet, e.g. from one main surface of the chiplet to the other (opposite) main surface of the chiplet). The plurality of through-chiplet vias forming the second vertical leg 1102d of the first turn 1102 are electrically connected in series. Furthermore, a first (in FIG. 11A upper) end of the second vertical leg 1102d of the first turn 1102 is connected to a second end of the first horizontal arm 1102a of the first turn 1102. The second horizontal arm 1102b of the first turn 1102 is formed in or on or over the bottommost chiplet 118 of the 3D chiplet stack 700. A first end of the second horizontal arm 1102b of the first turn 1102 is connected to a second (in FIG. 11A bottom) end of the second vertical leg 1102d of the first turn 1102. Illustratively, a second end of the second horizontal arm 1102b of the first turn 1102 forms the end of the first turn 1102.

The second turn 1104 includes a first vertical leg 1104c, a first horizontal arm 1104a, a second vertical leg 1104d and a second horizontal arm 1104b, which are connected in series with each other. The first vertical leg 1104c of the second turn 1104 and the second vertical leg 1104d of the second turn 1104 are positioned between the first vertical leg 1102c of the first turn 1102 and the second vertical leg 1102d of the first turn 1102. A first (in FIG. 11A bottom) end of the first vertical leg 1104c is connected to the second end of the second horizontal arm 1102b of the first turn 1102. The first vertical leg 1104c of the second turn 1104 is formed by a plurality of through-chiplet vias (each through-chiplet via (e.g. through silicon via) extends completely through a respective chiplet, e.g. from one main surface of the chiplet to the other (opposite) main surface of the chiplet). The plurality of through-chiplet vias forming the first vertical leg 1104c of the second turn 1104 are electrically connected in series. The first horizontal arm 1104a of the second turn 1104 may be formed in or on or over the topmost chiplet 104 of the 3D chiplet stack 700. Furthermore, a second (in FIG. 11A upper) end of the first vertical leg 1104c of the second turn 1104 is connected to a first end of the first horizontal arm 1104a. The second vertical leg 1104d of the second turn 1104 is formed by a plurality of further through-chiplet vias (each through-chiplet via (e.g. through silicon via) extends completely through a respective chiplet, e.g. from one main surface of the chiplet to the other (opposite) main surface of the chiplet). The plurality of through-chiplet vias forming the second vertical leg 1104d of the second turn 1104 are electrically connected in series. Furthermore, a first (in FIG. 11A upper) end of the second vertical leg 1104d of the second turn 1104 is connected to a second end of the first horizontal arm 1104a of the second turn 1104. The second horizontal arm 1104b of the second turn 1104 is formed in or on or over the bottommost chiplet 118 of the 3D chiplet stack 700. A first end of the second horizontal arm 1104b of the second turn 1104 is connected to a second (in FIG. 11A bottom) end of the second vertical leg 1104d of the second turn 1104. Illustratively, a second end of the second horizontal arm 1104b of the second turn 1104 forms the end of the second turn 1104.

The third turn 1106 includes a first vertical leg 1106c, a first horizontal arm 1106a and a second vertical leg 1106d, which are connected in series with each other. The first vertical leg 1106c of the third turn 1106 and the second vertical leg 1106d of the third turn 1106 are positioned between the first vertical leg 1104c of the second turn 1104 and the second vertical leg 1104d of the second turn 1104. A first (in FIG. 11A bottom) end of the first vertical leg 1106c is connected to the second end of the second horizontal arm 1104b of the second turn 1104. The first vertical leg 1106c of the third turn 1106 is formed by a plurality of through-chiplet vias (each through-chiplet via (e.g. through silicon via) extends completely through a respective chiplet, e.g. from one main surface of the chiplet to the other (opposite) main surface of the chiplet). The plurality of through-chiplet vias forming the first vertical leg 1106c of the third turn 1106 are electrically connected in series. The first horizontal arm 1106a of the third turn 1106 may be formed in or on or over the topmost chiplet 104 of the 3D chiplet stack 700. Furthermore, a second (in FIG. 11A upper) end of the first vertical leg 1106c of the third turn 1106 is connected to a first end of the first horizontal arm 1106a. The second vertical leg 1106d of the third turn 1106 is formed by a plurality of further through-chiplet vias (each through-chiplet via (e.g. through silicon via) extends completely through a respective chiplet, e.g. from one main surface of the chiplet to the other (opposite) main surface of the chiplet). The plurality of through-chiplet vias forming the second vertical leg 1106d of the third turn 1106 are electrically connected in series. Furthermore, a first (in FIG. 11A upper) end of the second vertical leg 1106d of the third turn 1106 is connected to a second end of the first horizontal arm 1106a of the third turn 1106. Illustratively, a second end of the second vertical leg 1106d of the third turn 1106 forms the end of the third turn 1106 and provides a second terminal 1110 of the coil 1100.

In these aspects, the first turn 1102 has a first through-chiplet extension length representing the length of a vertical leg 1102c, 1102d of the first turn 1102 including a through-chiplet via of the first turn 1102 of at least one chiplet. The second turn 1104 has a second through-chiplet extension length representing the length of a vertical leg 1104c, 1104d of the second turn 1104 including a through-chiplet via of the second turn of at least one chiplet. The first through-chiplet extension length is the same as the second through-chiplet extension length.

An electrically conductive connection of the plurality of electrically conductive connections 1102a of the first turn 1102 and an electrically conductive connection 1104b of the plurality of electrically conductive connections of the second turn 1104 are disposed in different planes, wherein the planes are perpendicular to the main surfaces of the plurality of chiplets.

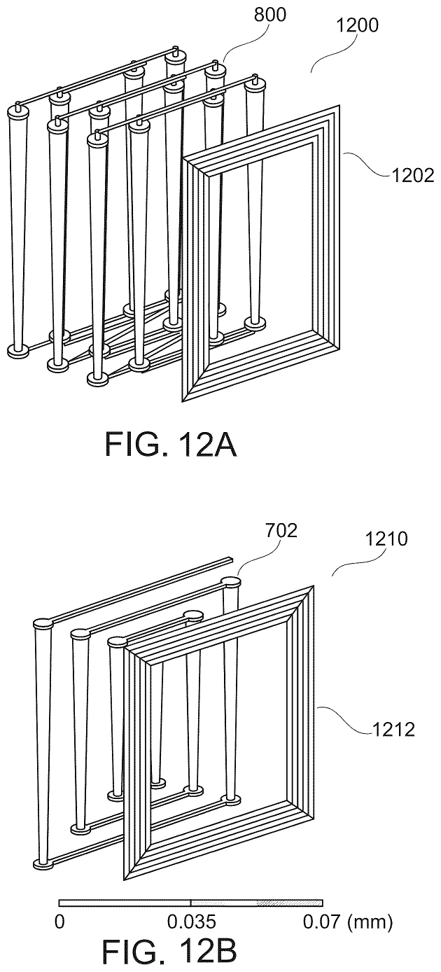

FIG. 12A depicts a simulated inductor system 1200 of the exemplary coil 800 of FIG. 8A and a host coil 1202. FIG. 12B depicts a simulated inductor system 1210 of the exemplary coil 702 of FIG. 9A and a host coil 1212.

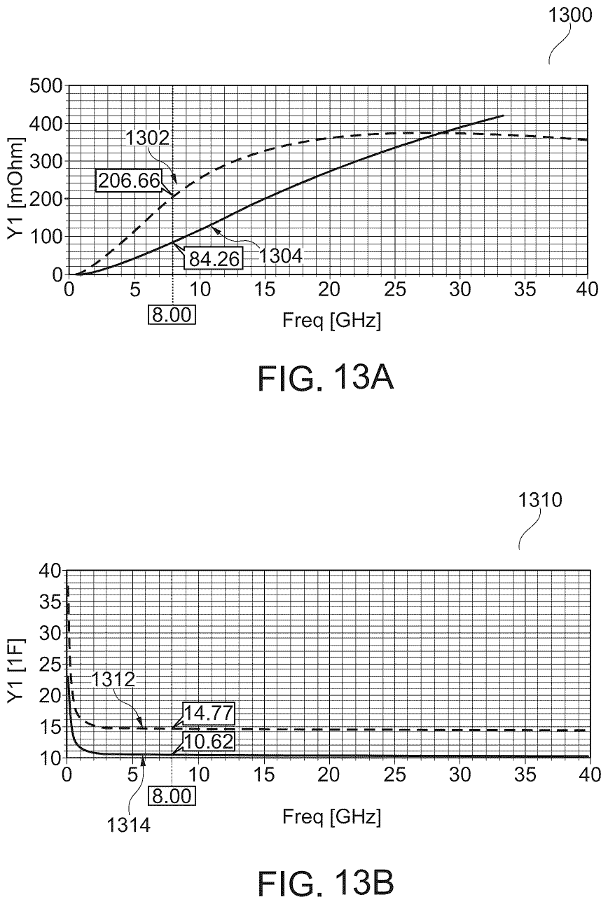

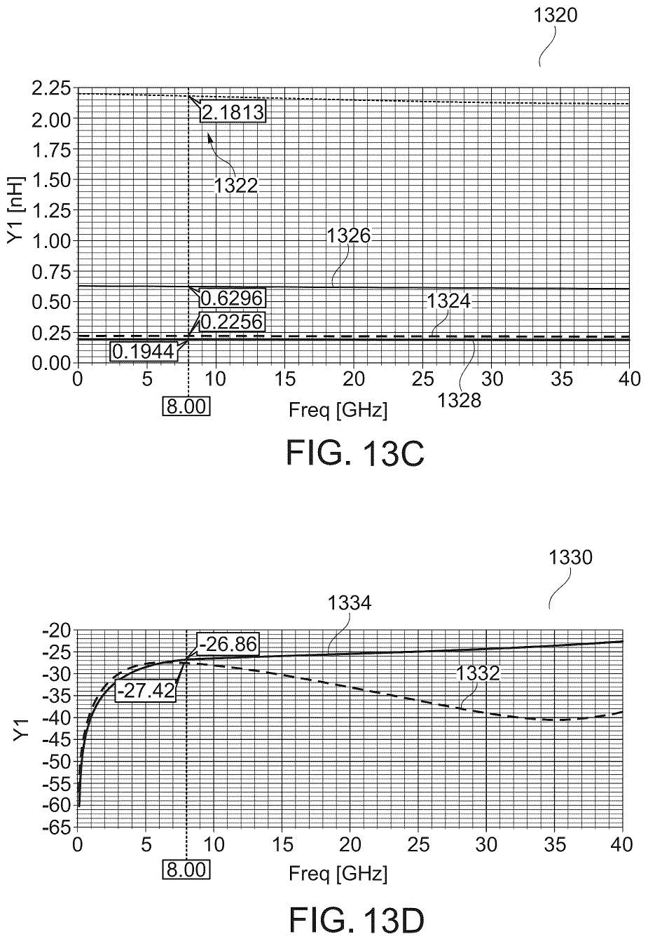

FIG. 13A depicts characteristics of the ohmic resistance versus frequency for the simulated inductor systems of FIG. 12A and FIG. 12B. In more detail, FIG. 13A shows a diagram 1300 illustrating simulated characteristics for the ohmic resistance in milliohm (mOhm) versus frequency in gigahertz (GHz) for the simulated inductor system 1200 of FIG. 12A (see first resistance characteristic 1302) and for the simulated inductor system 1210 of FIG. 12B (see second resistance characteristic 1304). As indicated in FIG. 13A, the coil 702 has an up to three times smaller ohmic resistance R compared to the Benchmark coil 800.

FIG. 13B depicts characteristics of the electric parasitic capacity versus frequency for the simulated inductor systems of FIG. 12A and FIG. 12B. In more detail, FIG. 13B shows a diagram 1310 illustrating simulated characteristics for the electric parasitic capacity in femtofarad (fF) versus frequency in gigahertz (GHz) for the simulated inductor system 1200 of FIG. 12A (see first parasitic capacity characteristic 1312) and for the simulated inductor system 1210 of FIG. 12B (see second parasitic capacity characteristic 1314). As indicated in FIG. 13B, the coil 702 has an up to 0.4 times smaller parasitic capacity (Cp) compared to the Benchmark coil 800.

The self-resonance frequency fᵣₑₛ of the respective coil is given by

$${f}_{r e s} = \frac{1}{2 π \sqrt{{L}_{s} {C}_{p}}} , \qquad ( 1 )$$

wherein Lₛ is the coil self-inductance and Cp is the coil parasitic capacity. Below fᵣₑₛ: the respective coil behaves like an inductor. The calculated fᵣₑₛ for both coils are 28 GHz for the Benchmark coil 800 vs 61.5 GHz for coil 702.

FIG. 13C depicts characteristics of the self-inductance versus frequency and of the mutual inductance versus frequency for the simulated inductor systems of FIG. 12A and FIG. 12B at 30 μm communication distance. In more detail, FIG. 13C shows a diagram 1320 illustrating simulated characteristics for the self-inductance and for the mutual inductance in nanohenry (nH) versus frequency in gigahertz (GHz) for the simulated inductor system 1200 of FIG. 12A (for the self-inductance Lₛ see first self-inductance characteristic 1322 and for the mutual inductance Lₘ see first mutual inductance characteristic 1324) and for the simulated inductor system 1210 of FIG. 12B (for the self-inductance Lₛ see second self-inductance characteristic 1326 and for the mutual inductance Lₘ see second mutual inductance characteristic 1328).

For a serial RLC circuit, the fractional bandwidth is given as

Δf=R/2πLₛ, (2)
which results in 15 MHz bandwidth for the Benchmark coil 800 vs 21.2 MHz bandwidth for the coil 702 (1.4 times higher).

FIG. 13D depicts characteristics of the link insertion loss (terminal S parameter) versus frequency for the simulated inductor systems of FIG. 12A and FIG. 12B. In more detail, FIG. 13D shows a diagram 1330 illustrating simulated characteristics for the link insertion loss in milliohm (mOhm) versus frequency in gigahertz (GHz) for the simulated inductor system 1200 of FIG. 12A (see first link insertion loss characteristic 1332) and for the simulated inductor system 1210 of FIG. 12B (see second link insertion loss 1334).

As shown in FIG. 13D, at 30 μm communication distance, the Benchmark coil 800 behaves as a LRC resonant circuit around 8 GHz while the resonance frequency of the coil 702 is well beyond 40 GHz, which indicates that the link can operate with much larger bandwidth and fast transition time.

It is to be noted that the coil(s) may extend through all chiplets of the plurality of chiplets of the 3D chiplet stack (e.g. the 3D chiplet stack 702, 1000).

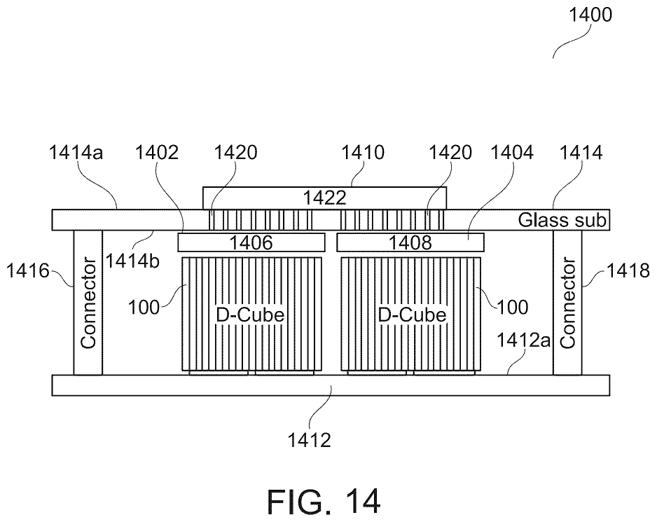

FIG. 14 shows an exemplary chip module 1400 according to an embodiment.

In this example, the chip module 1400 includes a plurality of (e.g. two) 3D chiplet stacks 100. Furthermore, the chip module 1400 includes a host die 1402, 1404 for each 3D chiplet stack 100. Each host die 1402, 1404 includes one or more host coils (not shown in FIG. 14). The one or more coils 702, 1000 of each 3D chiplet stack 100 are facing corresponding one or more host coils of the associated host die 1402, 1404 to provide an inductive coupling for transmission of data between the respective 3D chiplet stack 100 and the associated host die 1402, 1404. In various aspects, each host die 1402, 1404 includes one or more processors 1406, 1408 to provide management functions to manage the circuits (memory circuits and/or logic circuits) of the chiplets of the respectively associated 3D chiplet stack 100. By way of example, the one or more processors 1406, 1408 may provide a control of the reading/writing of data from/to memory cells in the chiplets of the respectively associated 3D chiplet stack 100. Furthermore the one or more processors 1406, 1408 may provide datapath logic to forward data from the chiplets of the respectively associated 3D chiplet stack 100 to a processor chip 1410. The 3D chiplet stacks 100, and the host dies 1402, 1404 are encapsulated by an encapsulation structure to form a package. The encapsulation structure may include a first substrate (e.g. a first glass substrate) 1412 and a second substrate (e.g. a second glass substrate) 1414. In various aspects, the first substrate 1412 and/or the second substrate 1414 may be formed from a different material than glass. In various aspects, the first substrate 1412 and/or the second substrate 1414 may be include organic material and thus form organic substrate(s). As an alternative, the first substrate 1412 and/or the second substrate 1414 may include or be silicon interposer(s). As a further alternative, the first substrate 1412 and/or the second substrate 1414 may include or be silicon caribe(s). Further alternative materials may be provided. The 3D chiplet stacks 100 are mounted on a first main surface 1412a of the first substrate 1412 and the host dies 1402, 1404 may be mounted on a first main surface of the second substrate 1414. Moreover, connector structures (e.g. metal structures) 1416, 1418 may be provided to connect one or more metal lines of the first substrate 1412 with one or more metal lines of the second substrate 1414. The encapsulation structure may further include encapsulating material (e.g. molding mass) at least partially encapsulating the plurality of chiplets and the electrically conductive connection. The second substrate 1414 may include a plurality of electrically conductive (e.g. metal) through-substrate vias 1420, which extend through the second substrate 1414 from a first main surface 1414a of the second substrate 1414 to a second main surface 1414b of the second substrate 1414. The first main surface 1414a of the second substrate 1414 and the second main surface 1414b of the second substrate 1414 are opposite to each other. The first main surface 1412a of the first substrate 1412 and the second main surface 1414b of the second substrate 1414 are facing each other. The chip module 1400 may further include the processor chip 1410 mounted on the first main surface 1414a of the second substrate 1414. The processor chip 1410 may be electrically coupled to the host dies 1402, 1404 via the electrically conductive through-substrate vias 1420. The processor chip 1410 may be implemented as a system-on-chip and may include one or more processors 1422. The one or more processors 1422 may be configured to implement any kind of desired processing functions such as signal processing function(s), graphics processing function(s), any kind of artificial intelligence function(s), and the like. The one or more processors 1422 may be configured to read data from memory cells of the chiplets of the 3D chiplet stacks 100, which are stored in the memory cells of the chiplets of the 3D chiplet stacks 100. The one or more processors 1422 may be configured to write data into memory cells of the chiplets of the 3D chiplet stacks 100 to store the data into memory cells of the chiplets of the 3D chiplet stacks 100.

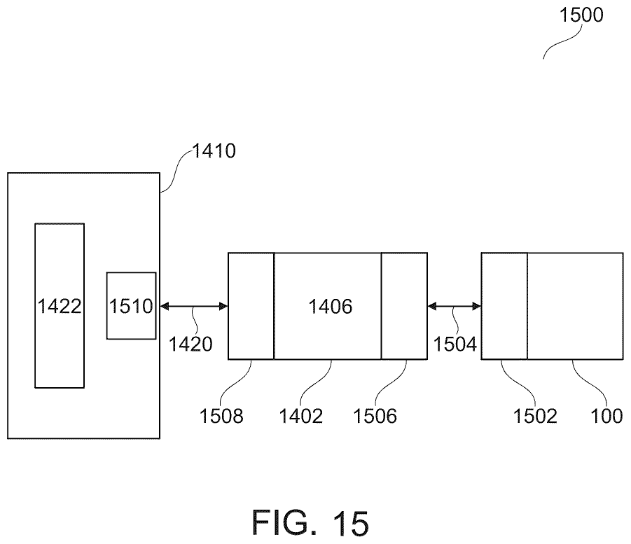

FIG. 15 depicts a block diagram 1500 illustrating the communication of data between the one or more processors 1422 of the processor chip 1420 of the chip module of FIG. 14.

As shown in FIG. 15, each 3D chiplet stack 100 may further include communication circuitry 1502 implementing PHY layer communication functions with respect to data communication between the 3D chiplet stack 100 and the associated host die 1402, 1404 using the inductive link(s) 1504 between the one or more coils 702, 1000 of the respective 3D chiplet stack 100 and the associated host die 1402, 1404. To implement this data communication using these inductive link(s) 1504, each host die 1402, 1404 may also include corresponding communication circuitry 1506 implementing PHY layer communication functions.

Each host die 1402, 1404 may further include further communication circuitry 1508 implementing PHY layer communication functions with respect to data communication between the respective host die 1402, 1404 and the processor chip 1420 using the electrically conductive through-substrate vias 1420. The further communication circuitry 1508 may be configured to provide an Advanced eXtensible Interface (AXI).

To implement this data communication using the electrically conductive through-substrate vias 1420, the processor chip 1410 may also include corresponding communication circuitry 1510 implementing PHY layer communication functions, e.g. providing an Advanced eXtensible Interface (AXI).

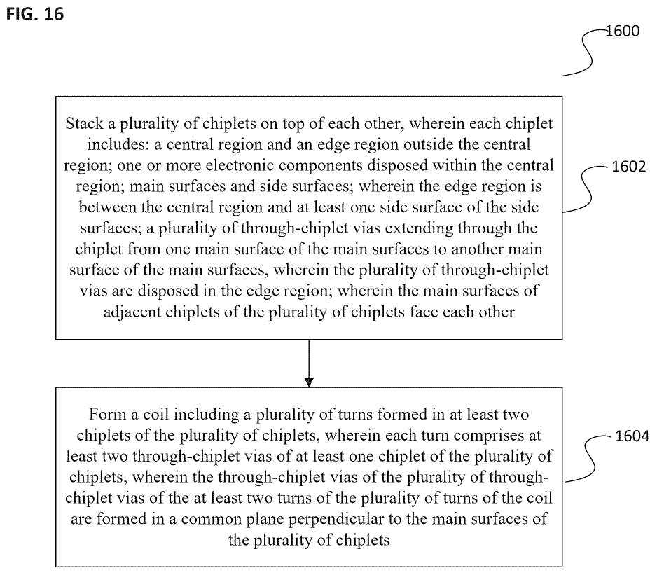

FIG. 16 depicts a flow diagram 1600 illustrating a method of manufacturing a device. The method 1600 may include, in 1602, stacking a plurality of chiplets on top of each other, wherein each chiplet includes: a central region and an edge region outside the central region; one or more electronic components disposed within the central region; main surfaces and side surfaces; wherein the edge region is between the central region and at least one side surface of the side surfaces; a plurality of through-chiplet vias extending through the chiplet from one main surface of the main surfaces to another main surface of the main surfaces, wherein the plurality of through-chiplet vias are disposed in the edge region; wherein the main surfaces of adjacent chiplets of the plurality of chiplets face each other. The method 1600 may further include, in 1604, forming a coil including a plurality of turns formed in at least two chiplets of the plurality of chiplets, wherein each turn includes at least two through-chiplet vias of at least one chiplet of the plurality of chiplets, wherein the through-chiplet vias of the plurality of through-chiplet vias of the at least two turns of the plurality of turns of the coil are formed in a common plane perpendicular to the main surfaces of the plurality of chiplets.

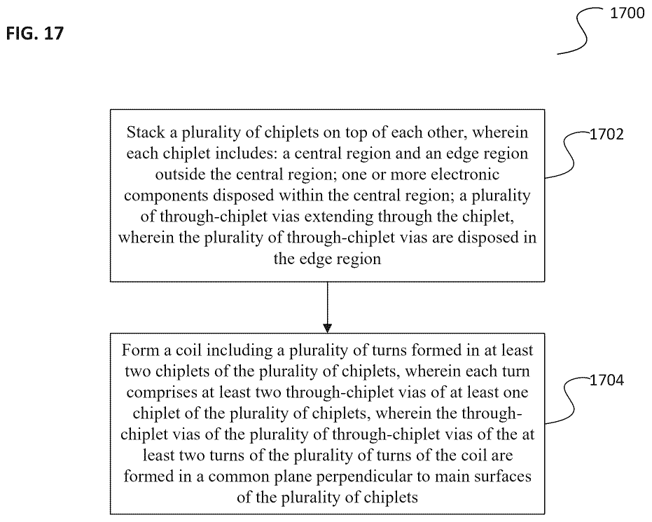

FIG. 17 depicts a flow diagram 1700 illustrating a method of manufacturing a device. The method 1700 may include, in 1702, stacking a plurality of chiplets on top of each other, wherein each chiplet includes: a central region and an edge region outside the central region; one or more electronic components disposed within the central region; a plurality of through-chiplet vias extending through the chiplet, wherein the plurality of through-chiplet vias are disposed in the edge region. The method 1700 may further include, in 1702, forming a coil including a plurality of turns formed in at least two chiplets of the plurality of chiplets, wherein each turn includes at least two through-chiplet vias of at least one chiplet of the plurality of chiplets, wherein the through-chiplet vias of the plurality of through-chiplet vias of the at least two turns of the plurality of turns of the coil are formed in a common plane perpendicular to main surfaces of the plurality of chiplets.

Additional aspects of the description will be disclosed by way of example:

Example 1 is a device. The device may include a plurality of chiplets stacked on top of each other. Each chiplet includes a central region and an edge region outside the central region; one or more electronic components disposed within the central region; and main surfaces and side surfaces. The edge region is between the central region and at least one side surface of the side surfaces. The device may further include a plurality of through-chiplet vias extending through the chiplet from one main surface of the main surfaces to another main surface of the main surfaces. The plurality of through-chiplet vias are disposed in the edge region. The main surfaces of adjacent chiplets of the plurality of chiplets face each other. The device may further include a coil including a plurality of turns formed in at least two chiplets of the plurality of chiplets. Each turn includes at least two through-chiplet vias of at least one chiplet of the plurality of chiplets. The through-chiplet vias of the plurality of through-chiplet vias of the at least two turns of the plurality of turns of the coil are formed in a common plane perpendicular to the main surfaces of the plurality of chiplets.

In Example 2, the subject matter of Example 1 can optionally include that each turn of the plurality of turns includes a plurality of electrically conductive connections between the at least two through-chiplet vias of a respective turn.

In Example 3, the subject matter of Example 2 can optionally include that at least one electrically conductive connection of the plurality of electrically conductive connections is disposed in a chiplet.

In Example 4, the subject matter of any one of Examples 1 to 3 can optionally include that the coil includes a first end terminal and a second end terminal.

In Example 5, the subject matter of Example 4 can optionally include that the first end terminal of the coil is electrically coupled to a reference potential structure.

In Example 6, the subject matter of Example 5 can optionally include that the reference potential structure is a grounding structure.

In Example 7, the subject matter of any one of Examples 5 or 6 can optionally include that the device further includes the reference potential structure.

In Example 8, the subject matter of any one of Examples 1 to 7 can optionally include that the device further includes a substrate (which may be a base die (also referred to as base chiplet) of the plurality of chiplets).

In Example 9, the subject matter of Example 8 can optionally include that the substrate includes the reference potential structure.

In Example 10, the subject matter of any one of Examples 4 to 9 can optionally include that the second end terminal of the coil is a controller terminal configured to receive a control potential to control the current flow through the coil.

In Example 11, the subject matter of Example 10 can optionally include that the first end terminal of the coil is a further controller terminal configured to receive a further control potential to control the current flow through the coil.

In Example 12, the subject matter of any one of Examples 10 or 11 can optionally include that the device further includes a controller coupled to the controller terminal.

In Example 13, the subject matter of Example 4 can optionally include that the second end terminal of the coil is a controller terminal configured to receive a control potential to control the current flow through the coil.

In Example 14, the subject matter of Example 13 can optionally include that the first end terminal of the coil is a further controller terminal configured to receive a further control potential to control the current flow through the coil.

In Example 15, the subject matter of any one of Examples 13 or 14 can optionally include that the device further includes a controller coupled to the controller terminal.

In Example 16, the subject matter of any one of Examples 12 or 15 can optionally include that the controller is electrically coupled to the further controller terminal.

In Example 17, the subject matter of any one of Examples 12 or 15 or 16 can optionally include that the controller is disposed in the substrate.

In Example 18, the subject matter of any one of Examples 1 to 17 can optionally include that the coil extends through all chiplets of the plurality of chiplets.

In Example 19, the subject matter of any one of Examples 1 to 18 can optionally include that the through-chiplet vias are through-silicon vias.

In Example 20, the subject matter of any one of Examples 1 to 19 can optionally include that a first turn of the plurality of turns has a first through-chiplet extension length representing the length of a coil leg of the first turn including a through-chiplet via of the first turn of at least one chiplet. A second turn of the plurality of turns has a second through-chiplet extension length representing the length of a coil leg of the second turn including a through-chiplet via of the second turn of at least one chiplet. The first through-chiplet extension length is larger than the second through-chiplet extension length.

In Example 21, the subject matter of any one of Examples 2 and 20 can optionally include that an electrically conductive connection of the plurality of electrically conductive connections of the first turn and an electrically conductive connection of the plurality of electrically conductive connections of the second turn are disposed in different chiplets of the plurality of chiplets.

In Example 22, the subject matter of any one of Examples 20 or 21 can optionally include that the first end terminal of the coil is an inner end terminal of the coil. The device may further include a further electrically conductive connection coupled to the first end terminal of the coil. The further electrically conductive connection extends outside the common plane perpendicular to the main surfaces of the plurality of chiplets.

In Example 23, the subject matter of Example 22 can optionally include that the further electrically conductive connection is coupled to a reference potential or a controller terminal.

In Example 24, the subject matter of any one of Examples 1 to 16 can optionally include that a first turn of the plurality of turns has a first through-chiplet extension length representing the length of a coil leg of the first turn including a through-chiplet via of the first turn of at least one chiplet. A second turn of the plurality of turns has a second through-chiplet extension length representing the length of a coil leg of the second turn including a through-chiplet via of the second turn of at least one chiplet. The first through-chiplet extension length is the same as the second through-chiplet extension length.

In Example 25, the subject matter of any one of Examples 2 and 24 can optionally include that an electrically conductive connection of the plurality of electrically conductive connections of the first turn and an electrically conductive connection of the plurality of electrically conductive connections of the second turn are disposed in the same chiplet of the plurality of chiplets.

In Example 26, the subject matter of Example 25 can optionally include that an electrically conductive connection of the plurality of electrically conductive connections of the first turn and an electrically conductive connection of the plurality of electrically conductive connections of the second turn are disposed in different planes perpendicular to the main surfaces of the plurality of chiplets. In other words, an electrically conductive connection of the plurality of electrically conductive connections of the first turn and an electrically conductive connection of the plurality of electrically conductive connections of the second turn are both running in different planes parallel to the main surfaces of the plurality of chiplets.

In Example 27, the subject matter of any one of Examples 1 to 26 can optionally include that the device further includes a die including one or more further electronic components; and a further coil disposed over a surface of the die and electrically connected to at least one further electronic component of the one or more further electronic components. The die and the coil are facing each other so that the further coil and the coil are inductively coupled with each other.

In Example 28, the subject matter of any one of Examples 1 to 27 can optionally include that the one or more electronic components include one or more memory cells.

In Example 29, the subject matter of Example 28 can optionally include that the one or more memory cells include one or more volatile memory cells.

In Example 30, the subject matter of any one of Examples 28 or 29 can optionally include that the one or more memory cells include one or more non-volatile memory cells.

In Example 31, the subject matter of any one of Examples 1 to 30 can optionally include that the one or more further electronic components include a logic circuit.

In Example 32, the subject matter of any one of Examples 1 to 31 can optionally include that the device further includes encapsulating material at least partially encapsulating the plurality of chiplets and the electrically conductive connection.

In Example 33, the subject matter of any one of Examples 1 to 32 can optionally include that the one or more electronic components include at least one of the following components: a logic circuit, e.g. a processor; or a memory circuit.

Example 34 is a device. The device may include a plurality of chiplets stacked on top of each other. Each chiplet includes: a central region and an edge region outside the central region; one or more electronic components disposed within the central region; and a plurality of through-chiplet vias extending through the chiplet, wherein the plurality of through-chiplet vias are disposed in the edge region. The device may further include a coil including a plurality of turns formed in at least two chiplets of the plurality of chiplets. Each turn includes at least two through-chiplet vias of at least one chiplet of the plurality of chiplets. The through-chiplet vias of the plurality of through-chiplet vias of the at least two turns of the plurality of turns of the coil are formed in a common plane perpendicular to main surfaces of the plurality of chiplets.

In Example 35, the subject matter of Example 34 can optionally include that each turn of the plurality of turns includes a plurality of electrically conductive connections between the at least two through-chiplet vias of a respective turn.

In Example 36, the subject matter of Example 35 can optionally include that at least one electrically conductive connection of the plurality of electrically conductive connections is disposed in a chiplet.

In Example 37, the subject matter of any one of Examples 34 to 36 can optionally include that the coil includes a first end terminal and a second end terminal.

In Example 38, the subject matter of Example 37 can optionally include that the first end terminal of the coil is electrically coupled to a reference potential structure.

In Example 39, the subject matter of Example 38 can optionally include that the reference potential structure is a grounding structure.

In Example 40, the subject matter of any one of Examples 38 or 39 can optionally include that the device further includes the reference potential structure.

In Example 41, the subject matter of any one of Examples 34 to 40 can optionally include that the device further includes a substrate (which may be a base die (also referred to as base chiplet) of the plurality of chiplets).

In Example 42, the subject matter of Example 41 can optionally include that the substrate includes the reference potential structure.

In Example 43, the subject matter of any one of Examples 37 to 42 can optionally include that the second end terminal of the coil is a controller terminal configured to receive a control potential to control the current flow through the coil.

In Example 44, the subject matter of Example 43 can optionally include that the first end terminal of the coil is a further controller terminal configured to receive a further control potential to control the current flow through the coil.

In Example 45, the subject matter of any one of Examples 43 or 44 can optionally include that the device further includes a controller coupled to the controller terminal.

In Example 46, the subject matter of Example 45 can optionally include that the controller is electrically coupled to the further controller terminal.

In Example 47, the subject matter of Example 38 can optionally include that the second end terminal of the coil is a controller terminal configured to receive a control potential to control the current flow through the coil.

In Example 48, the subject matter of Example 47 can optionally include that the first end terminal of the coil is a further controller terminal configured to receive a further control potential to control the current flow through the coil.

In Example 49, the subject matter of any one of Examples 47 or 48 can optionally include that the device further includes a controller coupled to the controller terminal.

In Example 50, the subject matter of any one of Examples 47 or 49 can optionally include that the controller is electrically coupled to the further controller terminal.

In Example 51, the subject matter of any one of Examples 45 to 50 can optionally include that the controller is disposed in the substrate.

In Example 52, the subject matter of any one of Examples 34 to 51 can optionally include that the coil extends through all chiplets of the plurality of chiplets.

In Example 53, the subject matter of any one of Examples 34 to 52 can optionally include that the through-chiplet vias are through-silicon vias.

In Example 54, the subject matter of any one of Examples 34 to 53 can optionally include that a first turn of the plurality of turns has a first through-chiplet extension length representing the length of a coil leg of the first turn including a through-chiplet via of the first turn of at least one chiplet. A second turn of the plurality of turns has a second through-chiplet extension length representing the length of a coil leg of the second turn including a through-chiplet via of the second turn of at least one chiplet. The first through-chiplet extension length is larger than the second through-chiplet extension length.

In Example 55, the subject matter of any one of Examples 35 and 54 can optionally include that an electrically conductive connection of the plurality of electrically conductive connections of the first turn and an electrically conductive connection of the plurality of electrically conductive connections of the second turn are disposed in different chiplets of the plurality of chiplets.

In Example 56, the subject matter of any one of Examples 54 or 55 can optionally include that the first end terminal of the coil is an inner end terminal of the coil; and that the device further includes a further electrically conductive connection coupled to the first end terminal of the coil. The further electrically conductive connection extends outside the common plane perpendicular to the main surfaces of the plurality of chiplets.

In Example 57, the subject matter of Example 56 can optionally include that the further electrically conductive connection is coupled to a reference potential or a controller terminal.

In Example 58, the subject matter of any one of Examples 34 to 53 can optionally include that a first turn of the plurality of turns has a first through-chiplet extension length representing the length of a coil leg of the first turn including a through-chiplet via of the first turn of at least one chiplet. A second turn of the plurality of turns has a second through-chiplet extension length representing the length of a coil leg of the second turn including a through-chiplet via of the second turn of at least one chiplet. The first through-chiplet extension length is the same as the second through-chiplet extension length.

In Example 59, the subject matter of any one of Examples 35 and 58 can optionally include that an electrically conductive connection of the plurality of electrically conductive connections of the first turn and an electrically conductive connection of the plurality of electrically conductive connections of the second turn are disposed in the same chiplet of the plurality of chiplets.

In Example 60, the subject matter of Example 59 can optionally include that an electrically conductive connection of the plurality of electrically conductive connections of the first turn and an electrically conductive connection of the plurality of electrically conductive connections of the second turn are disposed in different planes perpendicular to the main surfaces of the plurality of chiplets. In other words, an electrically conductive connection of the plurality of electrically conductive connections of the first turn and an electrically conductive connection of the plurality of electrically conductive connections of the second turn are both running in different planes parallel to the main surfaces of the plurality of chiplets.

In Example 61, the subject matter of any one of Examples 34 to 60 can optionally include that the device further includes a die including one or more further electronic components; and a further coil disposed over a surface of the die and electrically connected to at least one further electronic component of the one or more further electronic components. The die and the coil are facing each other so that the further coil and the coil are inductively coupled with each other.

In Example 62, the subject matter of any one of Examples 34 to 61 can optionally include that the one or more electronic components include one or more memory cells.

In Example 63, the subject matter of Example 62 can optionally include that the one or more memory cells include one or more volatile memory cells.

In Example 64, the subject matter of any one of Examples 62 or 63 can optionally include that the one or more memory cells include one or more non-volatile memory cells.

In Example 65, the subject matter of any one of Examples 34 to 64 can optionally include that the one or more further electronic components include a logic circuit.

In Example 66, the subject matter of any one of Examples 34 to 65 can optionally include that the device further includes encapsulating material at least partially encapsulating the plurality of chiplets and the electrically conductive connection.

In Example 67, the subject matter of any one of Examples 34 to 66 can optionally include that the one or more electronic components include at least one of the following components: a logic circuit, e.g. a processor; or a memory circuit.

Example 68 is a method of manufacturing a device. The method may include stacking a plurality of chiplets on top of each other. Each chiplet includes a central region and an edge region outside the central region; one or more electronic components disposed within the central region; and main surfaces and side surfaces. The edge region is between the central region and at least one side surface of the side surfaces. The method may further include a plurality of through-chiplet vias extending through the chiplet from one main surface of the main surfaces to another main surface of the main surfaces. The plurality of through-chiplet vias are disposed in the edge region. The main surfaces of adjacent chiplets of the plurality of chiplets face each other. The method may further include forming a coil including a plurality of turns formed in at least two chiplets of the plurality of chiplets. Each turn includes at least two through-chiplet vias of at least one chiplet of the plurality of chiplets. The through-chiplet vias of the plurality of through-chiplet vias of the at least two turns of the plurality of turns of the coil are formed in a common plane perpendicular to the main surfaces of the plurality of chiplets.

In Example 69, the subject matter of Example 68 can optionally include that each turn of the plurality of turns includes a plurality of electrically conductive connections between the at least two through-chiplet vias of a respective turn.

In Example 70, the subject matter of Example 69 can optionally include that at least one electrically conductive connection of the plurality of electrically conductive connections is formed in a chiplet.

In Example 71, the subject matter of any one of Examples 68 to 70 can optionally include that the coil includes a first end terminal and a second end terminal.

In Example 72, the subject matter of Example 71 can optionally include that the method further includes electrically coupling the first end terminal of the coil to a reference potential structure.

In Example 73, the subject matter of Example 73 can optionally include that the reference potential structure is a grounding structure.

In Example 74, the subject matter of any one of Examples 72 or 73 can optionally include that the method further includes forming the reference potential structure.

In Example 75, the subject matter of any one of Examples 68 to 74 can optionally include that the method further includes proving a substrate (which may be a base die (also referred to as base chiplet) of the plurality of chiplets).

In Example 76, the subject matter of Example 75 can optionally include that the substrate includes the reference potential structure.

In Example 77, the subject matter of any one of Examples 71 to 76 can optionally include that the second end terminal of the coil is a controller terminal configured to receive a control potential to control the current flow through the coil.

In Example 78, the subject matter of Example 77 can optionally include that the first end terminal of the coil is a further controller terminal configured to receive a further control potential to control the current flow through the coil.

In Example 79, the subject matter of any one of Examples 77 or 78 can optionally include that the method further includes providing a controller coupled to the controller terminal.

In Example 80, the subject matter of Example 71 can optionally include that the second end terminal of the coil is a controller terminal configured to receive a control potential to control the current flow through the coil.

In Example 81, the subject matter of Example 80 can optionally include that the first end terminal of the coil is a further controller terminal configured to receive a further control potential to control the current flow through the coil.

In Example 82, the subject matter of any one of Examples 80 or 81 can optionally include that the method further includes providing a controller coupled to the controller terminal.

In Example 83, the subject matter of any one of Examples 79 or 82 can optionally include that the device further includes electrically coupling the controller to the further controller terminal.

In Example 84, the subject matter of any one of Examples 79 or 82 or 83 can optionally include that the controller is disposed in the substrate.

In Example 85, the subject matter of any one of Examples 68 to 84 can optionally include that the coil extends through all chiplets of the plurality of chiplets.

In Example 86, the subject matter of any one of Examples 68 to 85 can optionally include that the through-chiplet vias are through-silicon vias.

In Example 87, the subject matter of any one of Examples 68 to 86 can optionally include that a first turn of the plurality of turns has a first through-chiplet extension length representing the length of a coil leg of the first turn including a through-chiplet via of the first turn of at least one chiplet. A second turn of the plurality of turns has a second through-chiplet extension length representing the length of a coil leg of the second turn including a through-chiplet via of the second turn of at least one chiplet. The first through-chiplet extension length is larger than the second through-chiplet extension length.

In Example 88, the subject matter of any one of Examples 69 and 87 can optionally include that an electrically conductive connection of the plurality of electrically conductive connections of the first turn and an electrically conductive connection of the plurality of electrically conductive connections of the second turn are disposed in different chiplets of the plurality of chiplets.

In Example 89, the subject matter of any one of Examples 87 or 88 can optionally include that the first end terminal of the coil is an inner end terminal of the coil. The method further includes coupling a further electrically conductive connection to the first end terminal of the coil. The further electrically conductive connection extends outside the common plane perpendicular to the main surfaces of the plurality of chiplets.

In Example 90, the subject matter of Example 89 can optionally include that the further electrically conductive connection is coupled to a reference potential or a controller terminal.

In Example 91, the subject matter of any one of Examples 68 to 90 can optionally include that a first turn of the plurality of turns has a first through-chiplet extension length representing the length of a coil leg of the first turn including a through-chiplet via of the first turn of at least one chiplet. A second turn of the plurality of turns has a second through-chiplet extension length representing the length of a coil leg of the second turn including a through-chiplet via of the second turn of at least one chiplet. The first through-chiplet extension length is the same as the second through-chiplet extension length.

In Example 92, the subject matter of any one of Examples 69 and 91 can optionally include that an electrically conductive connection of the plurality of electrically conductive connections of the first turn and an electrically conductive connection of the plurality of electrically conductive connections of the second turn are disposed in the same chiplet of the plurality of chiplets.

In Example 93, the subject matter of Example 92 can optionally include that an electrically conductive connection of the plurality of electrically conductive connections of the first turn and an electrically conductive connection of the plurality of electrically conductive connections of the second turn are disposed in different planes perpendicular to the main surfaces of the plurality of chiplets. In other words, an electrically conductive connection of the plurality of electrically conductive connections of the first turn and an electrically conductive connection of the plurality of electrically conductive connections of the second turn are both running in different planes parallel to the main surfaces of the plurality of chiplets.

In Example 94, the subject matter of any one of Examples 68 to 93 can optionally include that the method further includes providing a die including one or more further electronic components; and a further coil disposed over a surface of the die and electrically connected to at least one further electronic component of the one or more further electronic components. The die and the coil are facing each other so that the further coil and the coil are inductively coupled with each other.

In Example 95, the subject matter of any one of Examples 68 to 94 can optionally include that the one or more electronic components include one or more memory cells.

In Example 96, the subject matter of Example 95 can optionally include that the one or more memory cells include one or more volatile memory cells.

In Example 97, the subject matter of any one of Examples 95 or 96 can optionally include that the one or more memory cells include one or more non-volatile memory cells.

In Example 98, the subject matter of any one of Examples 68 to 97 can optionally include that the one or more further electronic components include a logic circuit.

In Example 99, the subject matter of any one of Examples 68 to 98 can optionally include that the method further includes at least partially encapsulating the plurality of chiplets and the electrically conductive connection with encapsulating material.

In Example 100, the subject matter of any one of Examples 68 to 99 can optionally include that the one or more electronic components include at least one of the following components a logic circuit, e.g. a processor; or a memory circuit.

Example 101 is a method of manufacturing a device. The method may include stacking a plurality of chiplets on top of each other. Each chiplet includes a central region and an edge region outside the central region; one or more electronic components disposed within the central region; and a plurality of through-chiplet vias extending through the chiplet. The plurality of through-chiplet vias are disposed in the edge region. The method may further include forming a coil including a plurality of turns formed in at least two chiplets of the plurality of chiplets. Each turn includes at least two through-chiplet vias of at least one chiplet of the plurality of chiplets. The through-chiplet vias of the plurality of through-chiplet vias of the at least two turns of the plurality of turns of the coil are formed in a common plane perpendicular to main surfaces of the plurality of chiplets.

In Example 102, the subject matter of Example 101 can optionally include that each turn of the plurality of turns includes a plurality of electrically conductive connections between the at least two through-chiplet vias of a respective turn.

In Example 103, the subject matter of Example 102 can optionally include that at least one electrically conductive connection of the plurality of electrically conductive connections is disposed in a chiplet.

In Example 104, the subject matter of any one of Examples 101 to 103 can optionally include that the coil includes a first end terminal and a second end terminal.

In Example 105, the subject matter of Example 104 can optionally include that the method further includes electrically coupling the first end terminal of the coil to a reference potential structure.

In Example 106, the subject matter of Example 105 can optionally include that the reference potential structure is a grounding structure.

In Example 107, the subject matter of any one of Examples 105 or 106 can optionally include that the method further includes providing the reference potential structure.

In Example 108, the subject matter of any one of Examples 101 to 107 can optionally include that the method further includes providing a substrate (which may be a base die (also referred to as base chiplet) of the plurality of chiplets).

In Example 109, the subject matter of Example 108 can optionally include that the substrate includes the reference potential structure.

In Example 110, the subject matter of any one of Examples 104 to 109 can optionally include that the second end terminal of the coil is a controller terminal configured to receive a control potential to control the current flow through the coil.

In Example 111, the subject matter of Example 110 can optionally include that the first end terminal of the coil is a further controller terminal configured to receive a further control potential to control the current flow through the coil.

In Example 112, the subject matter of any one of Examples 110 or 111 can optionally include that the method further includes coupling a controller to the controller terminal.

In Example 113, the subject matter of Example 112 can optionally include that the method further includes electrically coupling the controller to the further controller terminal.

In Example 114, the subject matter of Example 113 can optionally include that the second end terminal of the coil is a controller terminal configured to receive a control potential to control the current flow through the coil.

In Example 115, the subject matter of Example 114 can optionally include that the first end terminal of the coil is a further controller terminal configured to receive a further control potential to control the current flow through the coil.

In Example 116, the subject matter of any one of Examples 114 or 115 can optionally include that the method further includes coupling a controller to the controller terminal.

In Example 117, the subject matter of any one of Examples 114 or 116 can optionally include that the method further includes electrically coupling the controller to the further controller terminal.

In Example 118, the subject matter of any one of Examples 112 to 117 can optionally include that the controller is disposed in the substrate.

In Example 119, the subject matter of any one of Examples 101 to 118 can optionally include that the coil extends through all chiplets of the plurality of chiplets.

In Example 120, the subject matter of any one of Examples 101 to 119 can optionally include that the through-chiplet vias are through-silicon vias.

In Example 121, the subject matter of any one of Examples 101 to 120 can optionally include that a first turn of the plurality of turns has a first through-chiplet extension length representing the length of a coil leg of the first turn including a through-chiplet via of the first turn of at least one chiplet. A second turn of the plurality of turns has a second through-chiplet extension length representing the length of a coil leg of the second turn including a through-chiplet via of the second turn of at least one chiplet. The first through-chiplet extension length is larger than the second through-chiplet extension length.

In Example 122, the subject matter of any one of Examples 102 and 121 can optionally include that an electrically conductive connection of the plurality of electrically conductive connections of the first turn and an electrically conductive connection of the plurality of electrically conductive connections of the second turn are disposed in different chiplets of the plurality of chiplets.

In Example 123, the subject matter of any one of Examples 121 or 122 can optionally include that the first end terminal of the coil is an inner end terminal of the coil. The device further includes a further electrically conductive connection coupled to the first end terminal of the coil. The further electrically conductive connection extends outside the common plane perpendicular to the main surfaces of the plurality of chiplets.

In Example 124, the subject matter of Example 123 can optionally include that the method further includes coupling the further electrically conductive connection to a reference potential or a controller terminal.

In Example 125, the subject matter of any one of Examples 101 to 124 can optionally include that a first turn of the plurality of turns has a first through-chiplet extension length representing the length of a coil leg of the first turn including a through-chiplet via of the first turn of at least one chiplet. A second turn of the plurality of turns has a second through-chiplet extension length representing the length of a coil leg of the second turn including a through-chiplet via of the second turn of at least one chiplet. The first through-chiplet extension length is the same as the second through-chiplet extension length.

In Example 126, the subject matter of any one of Examples 102 and 125 can optionally include that an electrically conductive connection of the plurality of electrically conductive connections of the first turn and an electrically conductive connection of the plurality of electrically conductive connections of the second turn are disposed in the same chiplet of the plurality of chiplets.

In Example 127, the subject matter of Example 126 can optionally include that an electrically conductive connection of the plurality of electrically conductive connections of the first turn and an electrically conductive connection of the plurality of electrically conductive connections of the second turn are disposed in different planes perpendicular to the main surfaces of the plurality of chiplets. In other words, an electrically conductive connection of the plurality of electrically conductive connections of the first turn and an electrically conductive connection of the plurality of electrically conductive connections of the second turn are both running in a plane parallel to the main surfaces of the plurality of chiplets.

In Example 128, the subject matter of any one of Examples 101 to 127 can optionally include that the method further includes providing a die including one or more further electronic components; and a further coil disposed over a surface of the die and electrically connected to at least one further electronic component of the one or more further electronic components. The die and the coil are facing each other so that the further coil and the coil are inductively coupled with each other.

In Example 129, the subject matter of any one of Examples 101 to 128 can optionally include that the one or more electronic components include one or more memory cells.

In Example 130, the subject matter of Example 129 can optionally include that the one or more memory cells include one or more volatile memory cells.

In Example 131, the subject matter of any one of Examples 129 or 130 can optionally include that the one or more memory cells include one or more non-volatile memory cells.

In Example 132, the subject matter of any one of Examples 101 to 131 can optionally include that the one or more further electronic components include a logic circuit.

In Example 133, the subject matter of any one of Examples 101 to 132 can optionally include that the method further includes at least partially encapsulating the plurality of chiplets and the electrically conductive connection with encapsulating material.

In Example 134, the subject matter of any one of Examples 101 to 133 can optionally include that the one or more electronic components include at least one of the following components: a logic circuit, e.g. a processor; or a memory circuit.

While the above descriptions and connected figures may depict components as separate elements, skilled persons will appreciate the various possibilities to combine or integrate discrete elements into a single element. Such may include combining two or more circuits for form a single circuit, mounting two or more circuits onto a common chip or chassis to form an integrated element, executing discrete software components on a common processor core, etc. Conversely, skilled persons will recognize the possibility to separate a single element into two or more discrete elements, such as splitting a single circuit into two or more separate circuits, separating a chip or chassis into discrete elements originally provided thereon, separating a software component into two or more sections and executing each on a separate processor core, etc.

It is appreciated that implementations of methods detailed herein are demonstrative in nature, and are thus understood as capable of being implemented in a corresponding device. Likewise, it is appreciated that implementations of devices detailed herein are understood as capable of being implemented as a corresponding method. It is thus understood that a device corresponding to a method detailed herein may include one or more components configured to perform each aspect of the related method.

All acronyms defined in the above description additionally hold in all claims included herein.

What is claimed is:

1. A device, comprising,
a plurality of chiplets stacked on top of each other,
wherein each chiplet comprises:
a central region and an edge region outside the central region;
one or more electronic components disposed within the central region;
main surfaces and side surfaces;
wherein the edge region is between the central region and at least one side surface of the side surfaces;
a plurality of through-chiplet vias extending through the chiplet from one main surface of the main surfaces to another main surface of the main surfaces, wherein the plurality of through-chiplet vias are disposed in the edge region;
wherein the main surfaces of adjacent chiplets of the plurality of chiplets face each other;
a coil comprising a plurality of turns formed in at least two chiplets of the plurality of chiplets, wherein each turn comprises at least two through-chiplet vias of at least one chiplet of the plurality of chiplets;
wherein the through-chiplet vias of the plurality of through-chiplet vias of the at least two turns of the plurality of turns of the coil are formed in a common plane perpendicular to the main surfaces of the plurality of chiplets.

2. The device of claim 1,
wherein each turn of the plurality of turns comprises a plurality of electrically conductive connections between the at least two through-chiplet vias of a respective turn.

3. The device of claim 2,
wherein at least one electrically conductive connection of the plurality of electrically conductive connections is disposed in a chiplet.

4. The device of claim 1,
wherein the coil extends through all chiplets of the plurality of chiplets.

5. The device of claim 1,
wherein a first turn of the plurality of turns has a first through-chiplet extension length representing the length of a coil leg of the first turn comprising a through-chiplet via of the first turn of at least one chiplet;
wherein a second turn of the plurality of turns has a second through-chiplet extension length representing the length of a coil leg of the second turn comprising a through-chiplet via of the second turn of at least one chiplet; and
wherein the first through-chiplet extension length is larger than the second through-chiplet extension length.

6. The device of claim 1,
wherein each turn of the plurality of turns comprises a plurality of electrically conductive connections between the at least two through-chiplet vias of a respective turn;
wherein a first turn of the plurality of turns has a first through-chiplet extension length representing the length of a coil leg of the first turn comprising a through-chiplet via of the first turn of at least one chiplet;
wherein a second turn of the plurality of turns has a second through-chiplet extension length representing the length of a coil leg of the second turn comprising a through-chiplet via of the second turn of at least one chiplet; and
wherein the first through-chiplet extension length is larger than the second through-chiplet extension length; and
wherein an electrically conductive connection of the plurality of electrically conductive connections of the first turn and an electrically conductive connection of the plurality of electrically conductive connections of the second turn are disposed in different chiplets of the plurality of chiplets.

7. The device of claim 1,
wherein a first turn of the plurality of turns has a first through-chiplet extension length representing the length of a coil leg of the first turn comprising a through-chiplet via of the first turn of at least one chiplet;
wherein a second turn of the plurality of turns has a second through-chiplet extension length representing the length of a coil leg of the second turn comprising a through-chiplet via of the second turn of at least one chiplet; and
wherein the first through-chiplet extension length is the same as the second through-chiplet extension length.

8. The device of claim 1,
wherein each turn of the plurality of turns comprises a plurality of electrically conductive connections between the at least two through-chiplet vias of a respective turn;
wherein a first turn of the plurality of turns has a first through-chiplet extension length representing the length of a coil leg of the first turn comprising a through-chiplet via of the first turn of at least one chiplet;
wherein a second turn of the plurality of turns has a second through-chiplet extension length representing the length of a coil leg of the second turn comprising a through-chiplet via of the second turn of at least one chiplet;
wherein the first through-chiplet extension length is the same as the second through-chiplet extension length; and
wherein an electrically conductive connection of the plurality of electrically conductive connections of the first turn and an electrically conductive connection of the plurality of electrically conductive connections of the second turn are disposed in the same chiplet of the plurality of chiplets.

9. The device of claim 8,
wherein an electrically conductive connection of the plurality of electrically conductive connections of the first turn and an electrically conductive connection of the plurality of electrically conductive connections of the second turn are disposed in one or more planes parallel to the main surfaces of the plurality of chiplets.

10. The device of claim 1, further comprising:
a die comprising one or more further electronic components; and a further coil disposed over a surface of the die and electrically connected to at least one further electronic component of the one or more further electronic components;
wherein the die and the coil are facing each other so that the further coil and the coil are inductively coupled with each other.

11. The device of claim 1,
wherein the one or more electronic components comprise one or more memory cells.

12. A device, comprising,
a plurality of chiplets stacked on top of each other,
wherein each chiplet comprises:
a central region and an edge region outside the central region;
one or more electronic components disposed within the central region;
a plurality of through-chiplet vias extending through the chiplet, wherein the plurality of through-chiplet vias are disposed in the edge region;
a coil comprising a plurality of turns formed in at least two chiplets of the plurality of chiplets, wherein each turn comprises at least two through-chiplet vias of at least one chiplet of the plurality of chiplets;
wherein the through-chiplet vias of the plurality of through-chiplet vias of the at least two turns of the plurality of turns of the coil are formed in a common plane perpendicular to main surfaces of the plurality of chiplets.

13. The device of claim 12,
wherein each turn of the plurality of turns comprises a plurality of electrically conductive connections between the at least two through-chiplet vias of a respective turn.

14. The device of claim 12, further comprising:
a substrate (base die).

15. The device of claim 14,
wherein the substrate comprises the reference potential structure.

16. The device of claim 12,
wherein the coil extends through all chiplets of the plurality of chiplets.

17. The device of claim 12,
wherein a first turn of the plurality of turns has a first through-chiplet extension length representing the length of a coil leg of the first turn comprising a through-chiplet via of the first turn of at least one chiplet;
wherein a second turn of the plurality of turns has a second through-chiplet extension length representing the length of a coil leg of the second turn comprising a through-chiplet via of the second turn of at least one chiplet; and
wherein the first through-chiplet extension length is larger than the second through-chiplet extension length.

18. The device of claim 12,
wherein a first turn of the plurality of turns has a first through-chiplet extension length representing the length of a coil leg of the first turn comprising a through-chiplet via of the first turn of at least one chiplet;
wherein a second turn of the plurality of turns has a second through-chiplet extension length representing the length of a coil leg of the second turn comprising a through-chiplet via of the second turn of at least one chiplet; and
wherein the first through-chiplet extension length is the same as the second through-chiplet extension length.

19. A method of manufacturing a device, the method comprising,
stacking a plurality of chiplets on top of each other,
wherein each chiplet comprises:
a central region and an edge region outside the central region;
one or more electronic components disposed within the central region;
a plurality of through-chiplet vias extending through the chiplet, wherein the plurality of through-chiplet vias are disposed in the edge region;
forming a coil comprising a plurality of turns formed in at least two chiplets of the plurality of chiplets, wherein each turn comprises at least two through-chiplet vias of at least one chiplet of the plurality of chiplets;
wherein the through-chiplet vias of the plurality of through-chiplet vias of the at least two turns of the plurality of turns of the coil are formed in a common plane perpendicular to main surfaces of the plurality of chiplets.

20. The method of claim 19,
wherein each turn of the plurality of turns comprises a plurality of electrically conductive connections between the at least two through-chiplet vias of a respective turn.
